(19) United States
(12) Patent Application Publication
(10) Pub. No.: US 2025/0224729 A1
(43) Pub. Date: Jul. 10, 2025

(54) MULTISENSOR MEMS INERTIAL SENSOR GUIDANCE FOR AUTOMATIC VEHICLES

(71) Applicant: MEI Micro, Inc., Orlando, FL (US)

(72) Inventors: Robert Mark Boysel, Delaware, OH (US); Louis Ross, Tokyo (JP)

(21) Appl. No.: 18/922,266

(22) Filed: Oct. 21, 2024

Related U.S. Application Data
(63) Continuation-in-part of application No. PCT/US2023/019482, filed on Apr. 21, 2023.
(60) Provisional application No. 63/333,360, filed on Apr. 21, 2022.

(51) Int. Cl. G05D 1/245; B64G 1/24; B81B 7/00; G01C 19/5712; G01C 21/16; G01P 15/125; G05D 111/50

(52) U.S. Cl. CPC G05D 1/245; B64G 1/247; B81B 7/0074; G01C 19/5712; G01C 21/165; G01P 15/125; B81B 2201/0235; B81B 2201/0242; B81B 2207/012; B81B 2207/07; G05D 2111/52

(57) ABSTRACT

The present disclosure relates to a MEMS inertial sensor device in a semiconductor chip package that includes an integrated circuit configured to process inertial sensor data. Preferred implementations utilize inertial sensors having different sensitivity ranges to adjust operation of dynamic system control such as motion and or attitude control of autonomous vehicles.

### CROSS-REFERENCE TO RELATED APPLICATIONS

This is a continuation-in-part application of International Applic. No. PCT/US2023/019482 filed on Apr. 21, 2023, which claims priority to U.S. Provisional Application No. 63/333,360, filed on Apr. 21, 2022, the entire contents of these applications being incorporated herein by reference.

### TECHNICAL FIELD

The general technical field relates to Microelectromechanical Systems (MEMS) fabrication.

### BACKGROUND

Micro-electro-mechanical systems (MEMS) are an increasingly important enabling technology. MEMS inertial sensors are used to sense changes in the state of motion of an object, including changes in position, velocity, acceleration or orientation, and encompass devices such as accelerometers, resonators, gyroscopes, vibrometers and inclinometers. Broadly described, MEMS devices are integrated circuits (ICs) containing tiny mechanical, optical, magnetic, electrical, chemical, biological, or other, transducers or actuators. MEMS devices can be manufactured using high-volume silicon wafer fabrication techniques developed over the past fifty years for the microelectronics industry. Their resulting small size and low cost make them attractive for use in an increasing number of applications in a broad variety of industries including consumer, automotive, medical, aerospace, defense, green energy, industrial, and other markets.

### SUMMARY

As the sensitivity of inertial sensors can impact performance, a MEMS inertial sensor device having a plurality inertial sensor elements with different operating ranges can be fabricated to more accurately sense movement of an object undergoing a large range of accelerations, for example. Preferred implementations can include a multisensor chip package in which a plurality of inertial sensors are fabricated in a single chip package that includes one or more integrated circuits that process sensor signals generated by the inertial sensors within the chip package. The signal processing integrated circuitry can include system-on-chip (SOC) processing circuits and memory that can be mounted on a common circuit board to reduce latency as real time processing of inertial sensor data is critical for many applications such as the automated control of autonomous vehicles. Preferred embodiments incorporate the processing circuitry and one or more MEMS inertial sensors in a single chip package. The processing functions can include that high speed iterative computational processes used in machine learning operations used to control autonomous vehicles.

Preferred examples can include a plurality of accelerometers in which a first accelerometer measures a lower range of acceleration and a second accelerometer measures a higher range of acceleration. It is further advantageous to fabricate the plurality of MEMS sensors using a single fabrication process and preferably in a single chip package thereby providing alignment of the devices in a smaller area and weight and that operate at reduced power.

Preferred embodiments can be fabricated using a plurality of silicon-on-insulator (SOI) wafers that can be processed and fusion bonded together to provide a hermetically sealed chip package. There can preferably be two, three or four accelerometers fabricated on a single wafer, for example. Further embodiments can include different types of inertial sensors such as gyroscopes or can further include non-inertial sensors such as pressure sensors, time of flight (ToF) sensors and magnetometers. The sensor data can be processed and employed for navigation and/or platform and image stabilization, for example, using processing circuitry that can be included in the chip package in preferred embodiments. A processor can be programmed with sensor data fusion software to process the sensor data for specific applications. This type of sensor fusion is extensively used to obtain assured position, navigation and timing (A-PNT) in particular when a combination of sensors serves to extend the ability of a system to maintain precise navigation without the aid of GPS for extended periods of time (i.e. “dead reckoning”). In this example, the inertial sensors also help to support, aid and improve the performance of the other sensors that are part of the sensor fusion mix most of which are image sensors (including cameras, LIDAR, radar, and sonar). Another example includes the monitoring of all of the accelerometer outputs and using the output of the low range (high sensitivity) accelerometer unless it exceeds a preset threshold value. At this point the output of the high range accelerometer can be selected. In parallel, an impulse monitor (high-pass accelerometer operating at resonance) can be monitored. When the impulse monitor output signal amplitude rises above the average acceleration of the active filtered accelerometer, it is recorded as an impulse force that can be included in the dynamic calculation of velocity and position. Some specialized applications such as health and usage monitoring systems (HUMS), aka “Condition Monitoring” for various types of equipment exposed to high shock environments and autonomous vehicles require lower noise over higher frequency ranges and bandwidths beyond 10 KHz, high accuracy and very low size, weight, power (SWaP) requirements. Sensor fusion aims to reduce the complexities of various sensor data by improving the signal-to-noise ratio, decreasing uncertainty and increasing reliability, resolution and accuracy for longer periods of time. A fusion of sensors are used to compensate for other sensors' weaknesses to improve reliability especially in cases where data must be processed “on the fly” such as the case in dead reckoning situations involved in navigation. When computing resources are finite, artificial intelligence and machine learning can also support the determination of the best sensor data fusion strategy based on real-time operating conditions. This is particularly the case when implementing sensor fusion applications not only related to navigation but also in stand-alone Industry 4.0, Internet of Things (IoT), Internet of Moving Things (IoMT), machine vision and image processing applications.

Further embodiments include an inertial sensor chip package in which a processing circuit can be mounted on a circuit board or fabricated in a system-on-ship configuration that includes a system controller, a memory and a clock included in the MEMS chip or located with the processing circuit to control timing operations within the chip package. Such embodiments can further include a neural processing unit that performs iterative computational analysis of sensor data that is periodically sampled and can also be configured to perform sensor fusion operations with sensor data generated by a plurality of different sensors.

### BRIEF DESCRIPTION OF THE DRAWINGS

It is noted that the appended drawings illustrate only exemplary embodiments of the invention and are, therefore, not to be considered limiting of its scope, for the invention may admit to other equally effective embodiments.

FIG. 1 is an isometric top view of a 3DS multi-range accelerometer with two accelerometers covering up to two acceleration ranges.

FIG. 2 is an isometric view of the two-range accelerometer with the top cap removed to show the proof masses and support springs.

FIG. 3A is a cross-section drawing of the two-range accelerometer of FIG. 2 taken along the line A-B-C through the support springs of the two proof masses.

FIGS. 3B and 3C are an exploded view and schematic of the accelerometer of FIG. 3A.

FIG. 4 is an isometric view of the two-range accelerometer with the handle layer of the top cap removed to show the electrode arrangement.

FIG. 5 is an alternative embodiment of the multi-range accelerometer with four accelerometers covering up to four acceleration ranges.

FIG. 6 is the cross-section of FIG. 3A showing the two proof masses responding to an acceleration in the negative z direction larger than the mechanical range of one of the accelerometers.

FIG. 7 is one embodiment of the four-accelerometer of FIG. 5 illustrating various modes of operation.

FIG. 8A is a schematic, partially exploded perspective view of an integrated MEMS system, according to an embodiment. FIG. 8B is a schematic, exploded perspective view of the integrated MEMS system of FIG. 8A.

FIG. 9A is a schematic, cross-sectional view of an integrated MEMS system, according to another embodiment.

FIG. 9B is a schematic, cross-sectional view of an integrated circuit wafer.

FIG. 9C is a schematic, cross-sectional view of a MEMS wafer stack.

FIG. 9D is a schematic, cross-sectional view showing wafer-level flip bonding of the integrated circuit wafer of FIG. 9B to the MEMS wafer stack of FIG. 9C.

FIG. 9E is a schematic, cross-sectional view of the integrated MEMS system of FIG. 9A bonded to a printed circuit board (PCB).

FIG. 10A is a schematic representation of an integrated MEMS system, according to a preferred embodiment.

FIG. 10B schematically illustrates a further integrated MEMS system having onboard clocking and neural processing for computational analysis and/or feedback control of system operations.

FIG. 11 is a process flow diagram illustrating a method of operating a MEMS transducer device in accordance with preferred embodiments of the invention.

FIG. 12 is a process flow diagram illustrating a method of operating a proof mass MEMS device in accordance with preferred embodiments of the invention.

FIG. 13 is a schematic, cross-sectional view of an integrated MEMS system, according to a possible embodiment, shown bonded to a PCB.

FIG. 14 is an exemplary process flow diagram illustrating a software program for processing sensor data from a plurality of inertial sensors and optional non-inertial sensors for a variety of applications.

FIGS. 15A-B illustrate an exemplary neural network for that can be implemented on a neural processor for an inertial sensor in accordance with embodiments of the invention.

FIGS. 16A-B illustrate the integration of inertial measurement devices for autonomous vehicles in accordance with various embodiments of the invention.

FIG. 17 is a process flow diagram illustrating a method of measuring sensor data for an autonomous vehicle.

FIG. 18A is a schematic block diagram illustrating a phase adjustment procedure based upon a plurality of MEMS IMUs and a sensor platform IMU.

FIG. 18B is a schematic block diagram illustrating a phase adjustment procedure based upon an array MEMS IMUs and a navigation system INS, and optionally eliminating the platform IMU.

FIG. 18C is a process flow diagram illustrating a method of operating a MEMS transducer device in accordance with preferred embodiments of the invention.

FIG. 18D is a process flow diagram illustrating a method of operating a proof mass MEMS device in accordance with preferred embodiments of the invention.

FIG. 18E is a schematic illustration showing another possible embodiment of a sensor array mounted on an autonomous aircraft, in this case a synthetic aperture radar (SAR) in which one or more IMUs are mounted on the sensor array to measure motion of the array to provide compensation for emitted and detected signals.

FIG. 18F illustrates an antenna type in a satellite having a central IMU and additional IMUs as described herein for sensors distributed across the satellite array.

FIG. 19 is an illustration of a drone (or vehicle) that can fly autonomously.

FIG. 20 illustrates an example of a satellite system using distributed MEMS IMUs.

FIG. 21A is a graph of the position accuracy for Applicant IMU vs Automotive IMU over time.

FIG. 21B shows the measurement of an impulse or shock during a measurement period t with the 3DS accelerometer and the automotive accelerometer.

FIG. 22 is a diagram showing a high g impulse during a navigation scenario in which a machine learning computational process generates updated control signals for controlling the propulsion system of an autonomous vehicle.

### DETAILED DESCRIPTION

Systems and methods described herein relate to fabrication and use of an inertial sensor capable of sensing simultaneously multiple acceleration ranges within a hermetic package using Silicon-on-Insulator (SOI) wafers. As used herein, “g” refers to an amount of acceleration equal to the acceleration due to Earth's gravity.

In many applications, particularly those involving harsh or high-shock environments, it is desirable to have a high resolution (e.g., navigation grade with drift<100 ug), low range (e.g. range=1-10 g) accelerometer for navigation or tracking. However, shocks due to bumps or external disturbances can easily overdrive these low range accelerometers, leading to breaks or disruptions in the data used for navigation, for example. It is desirable to have at least one additional higher range (e.g. 10-100 g or >100 g) accelerometer to navigate through the shocks. Integrating multiple accelerometers for use in a single system leads to complications and cost in aligning the multiple devices to the same axis. In addition to these alignment issues, the use of multiple accelerometer chips adds additional area and weight to the sensor system footprint. For many modern navigation systems such as those used in drones and autonomous vehicles, space can be at a premium. Finally, high accuracy, low range accelerometers often use different sensing technologies from high g accelerometers. For example, most low g accelerometers use capacitive sensing while most high g accelerometers use piezoelectric or piezoresistive sensors. This can add complexity to the navigation system design. It is desirable then to have a multi-range accelerometer in which the multiple accelerometers are aligned and fabricated on the same integrated circuit substrate, preferably using a single process flow. Thus, a first MEMS inertial sensor having a first sensitivity S₁ can generate inertial data for a first operating condition, but if an error signal is generated above a threshold value that indicates that the first inertial sensor will not accurately report the change of state of the system, the system can switch to a second inertial sensor having a different second sensitivity S₂, that generates inertial data for a second operating condition.

Many MEMS devices cannot survive harsh or high shock environments. One of the main failure modes is the breaking of the proof mass from its support springs due to overextension of the springs during the shock event. Spring overextension is difficult to prevent using conventional packaging. It is thus also desirable to have the multi-range accelerometers packaged in a way to prevent overextension of the support springs.

In the following description, similar features in the drawings have been given similar reference numerals, and, in order to preserve clarity in the drawings, some reference numerals may be omitted when they were already identified in a preceding figure. It should also be understood that the elements of the drawings are not necessarily depicted to scale, since emphasis is placed upon clearly illustrating the elements and structures of the present embodiments.

### Embodiments of a Hermetic MEMS Inertial Sensor

In accordance with an aspect, there is provided a method of fabricating a multi-range accelerometer in a shock-resistant wafer-level package.

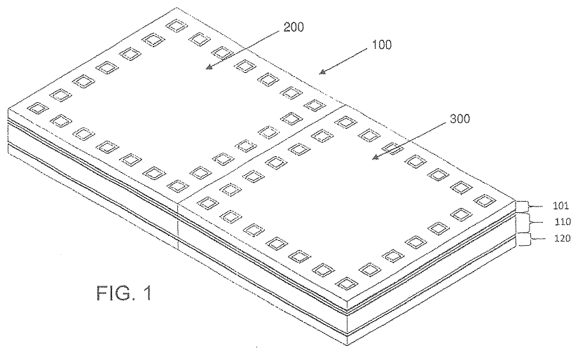

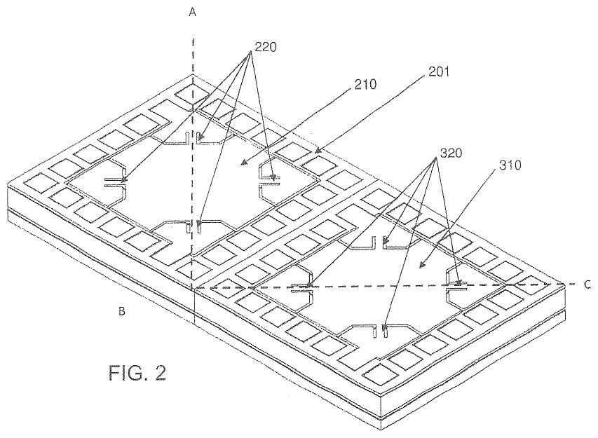

FIG. 1 shows an exemplary embodiment of a 3DS (3D System) MEMS multi-range accelerometer 100 fabricated using a 3DS fabrication process described herein. This particular embodiment includes two accelerometers 200 and 300 fabricated together on the same silicon chip to enable measurement of acceleration in two different ranges. As shown in FIG. 1, the accelerometer 100 can include a top cap wafer 101, a MEMS wafer 110, and a bottom cap wafer 120. Other embodiments with additional accelerometers with additional ranges can be implemented; however, the embodiment of FIG. 1 is illustrative of a fabrication method that can be applied to any number of accelerometers. FIG. 2 shows the embodiment of FIG. 1 with the top cap wafer 101 removed to show the accelerometer proof masses 210, 310.

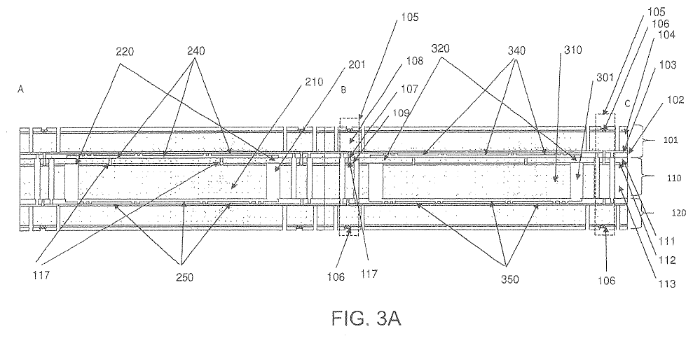

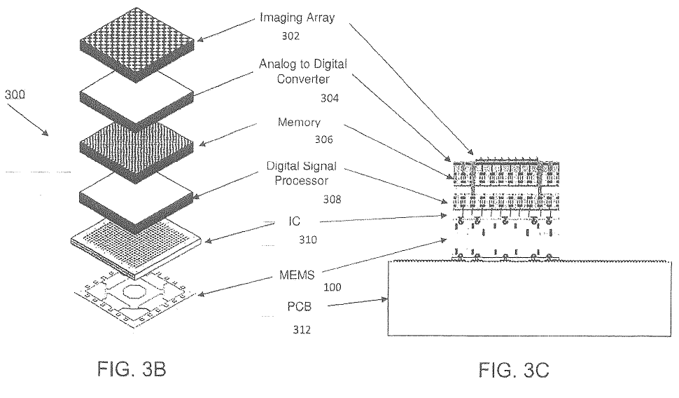

The 3DS process flow is now described briefly herein. Related process flows are suitable for use with the present systems and methods including the process flow using a plurality of SOI wafers to fabricate MEMS inertial sensors as described in U.S. Pat. No. 10,407,299, issued Sep. 10, 2019, and also described in U.S. Pat. No. 10,273,147, issued on Apr. 30, 2019, the entire contents of each of these patents being incorporated by reference herein. Some of the key features of the 3DS architecture are illustrated in FIG. 3A, which illustrates a cross section of FIGS. 1 and 2 taken along a line A-B-C through the support springs. The 3DS device architecture comprises the MEMS wafer 110, the top cap wafer 101, and the bottom 120 cap wafer. In preferred embodiments, this process can include fabricating features in a plurality of SOI wafers that can be bonded together, such as by high temperature fusion bonding, to form one or more inertial sensors in a chip package. The MEMS wafer 110 includes one or more MEMS structure(s), which can include or be embodied by any sensing and/or control element or combinations thereof such as, but not limited to, membranes, diaphragms, proof masses, actuators, transducers, micro-valves, micro-pumps, and the like. The MEMS wafer 110 has opposed first and second sides. The top cap wafer 101 and the bottom cap wafer 120 are respectively bonded to the first side and the second side of the MEMS wafer. The top cap wafer 101, the bottom cap wafer 120 and the MEMS wafer 110 are stacked along a stacking axis and they can form together one or more hermetic cavities 201,301 enclosing the MEMS structure. A MEMS structure can comprise sub-structures or elements contained in a cavity or chamber of the device. At least one of the top cap wafer 101 and the bottom cap wafer 120 is a silicon-on-insulator (SOI) cap wafer comprising a cap device layer 102, a cap handle layer 104 and a cap insulating layer 103 interposed between the cap device layer 102 and the cap handle layer 104. One of either the cap device layer or the cap handle layer has its inner side bonded to the MEMS wafer, and the other one of the cap handle layer or the cap device layer has its outer side provided with outer electrical contacts 106 formed thereon. At least one electrically conductive path 105 extends through the cap handle layer and through the cap device layer of the SOI cap wafer, to establish an electrical connection between one of the outer electrical contacts 106 and the MEMS structure. Although FIG. 3A illustrates the top cap wafer 101 as including the cap device, cap insulating, and cap handle layers, it should be understood that the bottom cap wafer 120 can be similarly constructed. Preferably, both the top and the bottom cap wafers are SOI wafers.

The electrically conductive path 105 can include a conducting shunt 107, formed through the cap insulating layer 103, electrically connecting the cap handle layer 104 and the cap device layer 102. A conducting shunt can be formed by etching a via or small area in the cap insulating layer 103 and depositing a conductive material therein, to electrically connect the cap device 102 and handle 104 layers of the SOI cap wafer 101, 120. The electrically conductive path 105 also comprises a post 108 formed in the cap handle layer 104, the post being delineated by a closed-loop trench patterned through the entire thickness of the cap handle layer 104. In this embodiment, one of the electrical contacts 106 is located on top of said post 108.

In some embodiments, the electrically conductive path 105 includes a pad 109 formed in the cap device layer 102, the pad being delineated by a trench patterned through an entire thickness of the cap device layer 102, the pad being aligned with the post. It is noted that by “aligned with” it is meant the pad 109 and post 108 are opposite each other along an axis parallel to the stacking axis, such that at least a portion of the pad 109 faces at least a portion of the post 108.

In some embodiments, the MEMS wafer is an SOI MEMS wafer 110 comprising a MEMS device layer 111 bonded to the top cap wafer 101, a MEMS handle layer 113 bonded to the bottom cap wafer 120, and a MEMS insulating layer 112 interposed between the MEMS device layer 111 and the MEMS handle layer 113.

Referring to FIGS. 2 and 3A, the MEMS wafer 110 comprises an outer frame 201, and the MEMS structure comprises at least one proof mass 210, 310 suspended by springs 220, 320. The proof mass is patterned in both the MEMS handle 113 and MEMS device 111 layers, and the springs 220, 320 are patterned in the MEMS device layer 111. This at least one proof mass includes conductive shunts 117 electrically connecting the MEMS device and handle layers, and the electrically conductive path 105 connects one of the electrical contacts to the MEMS structure via at least one of the springs. In possible embodiments, the electrically conductive path connecting an outer electrical contact located on the SOI cap wafer to the MEMS structure includes a post patterned in the cap handle layer, a pad patterned in the cap device layer, and a conductive shunt formed in the cap insulating layer, to connect the post with the pad; a pad patterned in the MEMS device layer, the pad being part of an outer frame; and a spring patterned in the MEMS device layer, the spring suspending the MEMS structure in the hermetic cavity.

In possible embodiments of the multi-range accelerometer, the cap device layer 102 comprises cap electrodes 240, 340 patterned therein. In some embodiments, the 3D MEMS device comprises additional electrically conductive paths that are not connected to the MEMS structures but are connected to electrodes provided in one of the caps. These additional electrically conductive paths extend through the cap handle layer and through the cap device layer. The portion of the path extending in the cap can be referred to as “cap feedthrough”. At least some of the additional electrically conductive paths establish an electrical connection between a subset of the outer electrical contacts and the cap electrodes. The cap electrodes can be located in either one of the cap wafers, and preferably in both caps.

Referring again to FIGS. 2 and 3A, a multi-range accelerometer includes two or more proof masses 210, 310 each suspended by one or more springs or flexures 220, 320. The sensitivity to acceleration of each proof mass is the displacement of the proof mass in response to acceleration. For motion Δz in response to acceleration in the z direction, perpendicular to the plane of the device, sensitivity Sz=Δz/a=M/K, where a is the acceleration, M is the mass of the proof mass, and K is the effective spring constant of the supporting springs. The lateral dimensions of the springs and or proof mass of each accelerometer can be designed to set sensitivity of each proof mass and spring assembly to a different desired range without modifying the thickness of the MEMS device layer or the MEMS handle layer, thus leaving the process flow unchanged. In other embodiments, the thickness of the device layer, the insulating layer and the handle layer can be configured for specific applications. In one example, the proof mass of a MEMS sensor device can comprise the device layer having a thickness in a range of 1-100 microns that is patterned to form a moving mass upon release from the underlying insulating layer. See for example, the MEMS magnetometer as shown and described in U.S. Pat. No. 11,287,486, issued Mar. 29, 2022, the entire contents of which is incorporated herein by reference. In a similar manner, for the embodiment shown in FIGS. 2 and 3A, acceleration along x and y in the plane of the springs results in an angular rotation Δθ of the proof masses and a sensitivity to acceleration in x or y directions of S_{x,y}=Δθ/a=J/κMr², where J is the moment of inertia of the proof mass, r is the radius of gyration of the proof mass (i.e., the distance from the axis of rotation to the center of mass), and κ is the effective torsional spring constant of the support springs. Both J and κ can be adjusted by modifying lateral dimensions of springs or proof mass in the design without modifying the process flow.

FIGS. 3B and 3C are an exploded view and schematic of the accelerometer of FIG. 3A. The figures show an imaging array 302 and an analog to digital converter 304. FIGS. 3B and 3C also show a memory 306 interfacing the digital signal processor 308. The digital signal processor 308 interfaces an integrated circuit 311 below it and they interface the MEMs device 100. They are mounted to a printed circuit board (PCB) 312.

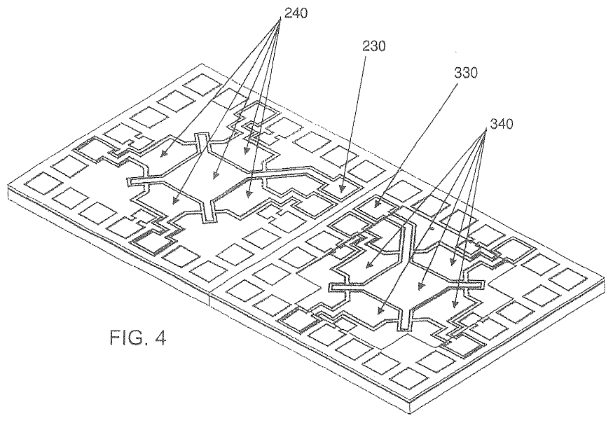

FIG. 4 shows a possible embodiment of the multi-range accelerometer 100 with the top cap handle layer 104 and the top cap insulating layer 103 removed to show an embodiment of electrode arrangement 240, 340. A similar set of electrodes reside on the device layer of the bottom cap wafer 120. The vertical deflection Δz or angular deflection 40 of each proof mass can be measured by measuring the differential capacitance between selected pairs of electrodes. These cap electrodes 240, 340 are electrically connected to leads 230, 330 that extend orthogonally to the stacking axis, and they form part of corresponding additional electrically conducting paths.

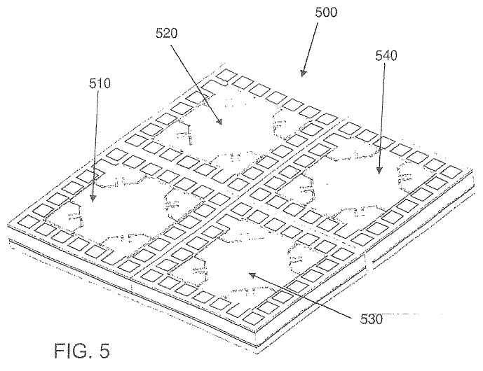

The number of accelerometer units can easily be increased by adding them to the sensor design layout, and the acceleration detection ranges of each accelerometer unit can easily be tuned by modifying spring and mass lateral dimensions. FIG. 5 illustrates an embodiment of the multi-range accelerometer 500 with four separate accelerometer units 510, 520, 530, 540 each covering a different range of acceleration values. The multi-range approach using the 3DS architecture has several advantages. The first is that the accelerometers are aligned with photolithographic accuracy. Previously, multiple conventional accelerometers were used to cover multiple ranges with each conventional accelerometer provided in an individual package, so each conventional accelerometer must be mechanically aligned to the others and mounted in an additional package. This can lead to alignment errors between the accelerometers and additional size and cost for assembly.

The resolution of an accelerometer is limited by its range. It is uncommon for an accelerometer to have a resolution much finer than 1 part in 10⁵ due to the limitations of electronic noise and A/D (analog to digital) conversion. Thus a +/−1 g accelerometer may be able to achieve 10 ug resolution, but if the measurement range is +/−1000 g, the resolution is more like 10 mg. So although it is desirable to keep the range low (high precision), if the sensor exceeds that range, the sensor may stop working correctly and acceleration data may be lost. In an extreme case of very high acceleration or shock impulses, the proof mass can be torn from the springs permanently damaging the sensor.

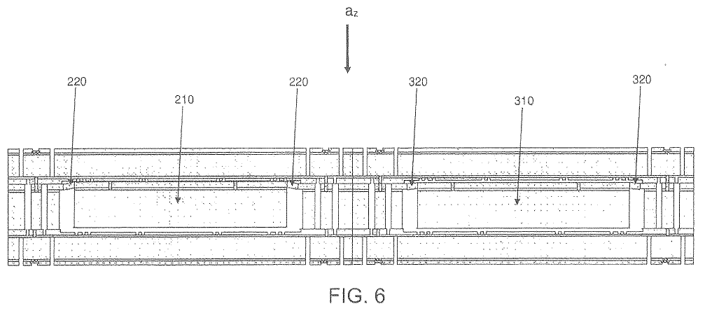

FIG. 6 shows the embodiment of FIGS. 2, 3A, and 4 under acceleration in the z direction. In this embodiment the springs 220 on one proof mass 210 are designed to be 100 times “softer” than the springs 320 on proof mass 310. That is, accelerometer 200 has a range, for example, of +/−1 g and accelerometer 300 has a range of, for example, +/−100 g. At low accelerations, the system can use signals from accelerometer 200 because it has the higher sensitivity. However, if a shock or high g acceleration occurs, accelerometer 200 can exceed its range and provide erroneous or interrupted signal output. In such an instance, the system can use signals from accelerometer 300 during high g acceleration or shock. In some embodiments, the 3DS architecture can include built-in shock protection. Because capacitor measurement gaps above and below the proof mass are only on the order of 1-5 microns wide, proof mass 210 cannot travel more than a few microns (even if it is overdriven) before the proof mass 210 contacts the top cap wafer 101. This limited motion range protects the sensor from shock damage by preventing over-extension of the springs or high-speed collision of the proof mass with surrounding features.

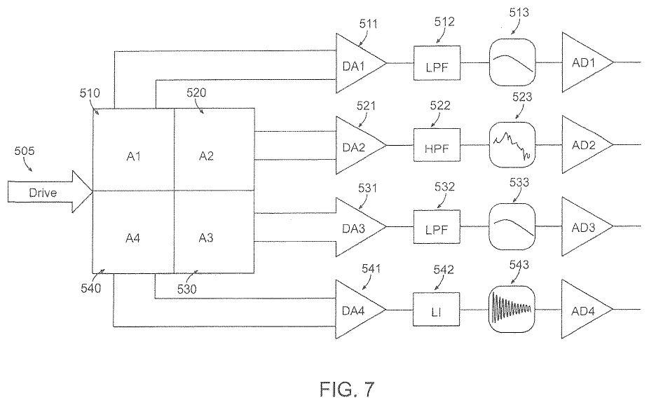

The 3DS multi-range accelerometer also allows for several modes of accelerometer operation. FIG. 7 is a block diagram of a multirange accelerometer 500 comprising 4 accelerometers 510, 520, 530, 540 similar to the embodiment in FIG. 5. Here accelerometers A1 and A2 (510, 520) are low-range accelerometers and A3 and A4 (530, 540) are high-range accelerometers. In some embodiments, the accelerometers can be operated in one of three modes: low pass, high pass, and tuned. In FIG. 7, all four accelerometers are driven with an AC drive signal (505). The differential capacitance signals from each of the accelerometers are amplified by differential amplifiers DA1 511, DA2 521, DA3 531, and DA4 541. In the embodiment of FIG. 7, the outputs of DA1 and DA3 are run through respective low pass filters 512, 532. This signal conditioning by low pass filter provides respective filtered, averaged values 513, 533 of the acceleration in a manner used by most commercial accelerometers. Because of the low-pass filtering, impulses and vibration are filtered out. The output of DA3 is run through a high pass filter 522. This enables the accelerometer to have a higher frequency output response, which enables measurement of vibration, shocks and impulses 523 longer than the resonant period of the accelerometer proof mass. This is a configuration typical of a vibration sensor or vibrometer. Accelerometer A4 540 is shown operated in an impulse mode. Here, the output of DA4 541 is monitored at the resonant frequency of the proof mass where the amplitude of the resonance 542 above a threshold is generated. A lock in amplifier (LI) can be used to provide a signal where the resonant frequency is used as a reference. High, short term impulses (frequency content higher than the resonant frequency of the proof mass) displace the proof mass, causing it to ring at the resonant frequency. By monitoring the amplitude of the ringing 543, the magnitude of the impulse can be computed. The embodiment illustrated in FIG. 7 shows how the 3DS multi-range accelerometer architecture can not only accommodate multiple ranges of acceleration, but also multiple modes of measurement. The specific association of each accelerometer in FIG. 7 with a block circuit diagram of one type or another is not intended to be limiting in that any circuit or combination of circuits can be used with any accelerometer in the multi-range accelerometer sensor depending upon the requirements of the measurement.

The multi-accelerometer chip package as described herein can be used in combination with gyroscope and other sensor components for inertial measurement units as described in US U.S. Pat. No. 10,214,414, issued Feb. 26, 2019, and U.S. application Ser. No. 14/622,548, filed on Feb. 13, 2015, the entire contents of this patent and application being incorporated herein by reference. The chip components which can include an internal clock for controlled timing of component operation can be assembled in a vertical stack and/or a lateral array and used for numerous applications for inertial navigation and stabilization of sensor platforms, autonomous vehicles, aircraft, unmanned aerial vehicles (UAVs), satellites such as those described in International Application No. PCT/US2017/015393 filed on Jan. 27, 2017 and published as WO 2017/132539 wherein the entire contents of this application is incorporated herein by reference.

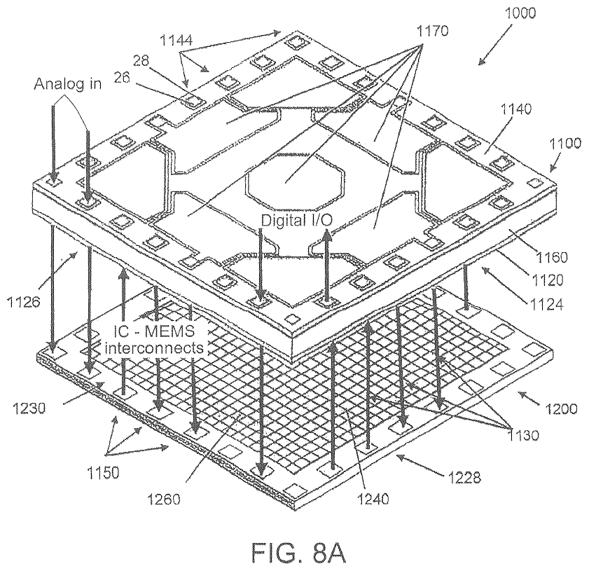

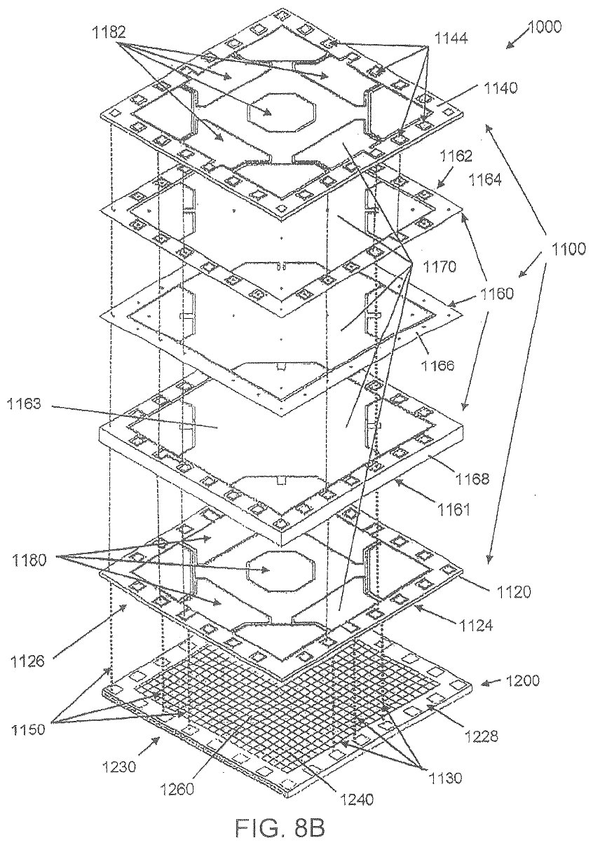

Referring to FIGS. 8A and 8B, a possible embodiment of an integrated MEMS system 1000 is shown. The system 1000 has an architecture that can enable MEMS sensor functions to be integrated into a single MEMS chip while the electronic functions can be integrated into a single IC chip. This architecture allows the passing of auxiliary signals through the MEMS chip(s), to be processed by the IC chip. The MEMS chip, which includes a plurality of insulated conducting pathways, some extending through the entire thickness of the MEMS chip, enables wire-bond-free electrical connections to an IC chip. Auxiliary signals are non-MEMS signals, i.e., external to the MEMS chip, which are provided by another component, such as a PCB for example. The IC chip can be flip-chip bonded to the top of the MEMS chip, either at the chip or wafer level, forming an integrated MEMS system, eliminating much of the cost of MEMS and IC integration, as well as packaging complications and costs described earlier. The MEMS system can also include several single MEMS chip(s) stacked vertically, and also possibly more than one integrated circuit chip wherein each chip includes separate sensor elements.

In this example, the integrated MEMS system 1000 comprises a single MEMS chip 1100, comprising a first cap layer 1120, a central MEMS layer 1160 and a second cap layer 1140. The layers 1120, 1160 and 1140 are made of an electrically conductive material, such as silicon having a doping level sufficient to conduct electrical signals through regions of the silicon configured with electrical contacts. The first cap layer 1120 is electrically bonded to a first side 1161 of the central MEMS layer 1160, and the second cap layer 1140 is electrically bonded to a second side 1162 of the central MEMS layer 1160, opposite the first side 1161.

The central MEMS layer 1160 is located between the first and second cap layers 1120, 1140, and is made of a silicon-on-insulator (SOI) wafer, including a device layer 1164, a handle layer 1168, and an insulating layer 1166. The first cap layer 1120, the central MEMS layer 1160 and the second cap layer 1140 are fabricated from respective silicon-based wafers, bonded at wafer level, as will be explained in more detail below. The insulating layer 1166 is an SOI buried oxide layer between the SOI device layer 1164 and SOI handle layer 1168. Conductive shunts are fabricated through the buried oxide layer 1166 to make an electrical connection between the SOI device and handle layers 1164, 1168 in specific desired places, for example as part of the insulated conducting pathways.

At least one transducer 1170 is formed in the first cap layer 1120, the central MEMS layer 1160 and the second cap layer 1140, for producing motion or sensing of at least one parameter. A transducer can be either a sensor, such as a motion sensor for example, or an actuator, such as a micro-switch for example. The one or more transducer(s) include(s) MEMS structures, for example proof masses for motion sensors, or membranes for pressure sensors or magnetometers. The architecture of the MEMS chip 1100, with two outer caps and a central MEMS layers, interconnected and made of electrically conductive material, allows to include several different types of transducer within a single MEMS chip. The MEMS structures are patterned in the central MEMS layer 1160, and first and second sets of electrodes 1180, 1182 are patterned in the first and second layers 1120, 1140, and are operatively linked (such as magnetically, capacitively, electrically, etc.) to the MEMS structures. A “single MEMS chip” is thus a chip encapsulating one or more MEMS transducers patterned in the two cap layers 1120 and 1140 and central MEMS layer 1160. The different MEMS features (i.e. electrodes, proof masses, membranes, leads, etc.) of the transducer(s) are patterned within the same silicon wafer, in contrast with having multiple MEMS chips adhesively attached side-by-side on a substrate, with each chip including different MEMS sensors. For example, the present architecture allows to pattern MEMS features to measure acceleration, angular rate and magnetic field along three different axes, as well as other sensors, such as a pressure sensor, within the same three wafer layers, and thus within the same MEMS chip.

Still referring to FIGS. 8A and 8B, the first cap layer 1120 includes electrical contacts 1124, 1126 on its outer side, preferably located around the periphery of the MEMS chip 1100. These electrical contacts of the first cap layer 1124, 1126 are referred to as first cap MEMS-electrical contacts. The second cap layer 1140 also includes electrical contacts 1144 on its outer side, referred to as second cap MEMS-electrical contacts. The first and second cap MEMS-electrical contacts 1124, 1126 and 1144 are typically bond pads.

The single MEMS chip 1100 also includes a plurality of insulated conducting pathways 1130, 1150, extending through one or more of the first cap layer 1120, central MEMS layer 1160 and second layer 1140. The MEMS chip thus comprises electrically isolated “three dimensional through-chip vias” (3DTCVs) to transmit signals through the MEMS wafer layers 1160, to and through the cap layers 1120, 1140, to bond pads 1124, 1144 on the outer sides of the MEMS chip. The insulated conducting pathways 1130, 1150 can extend in one or more directions. The insulated conducting pathways 1130, 1150 can be formed using a silicon “trench-and-fill” process. The insulated conducting pathways 1130, 1150 are typically formed by insulated closed-looped trenches 28 surrounding conductive wafer plugs 26. The trenches 28 are filled with an insulating material and the conductive wafer plugs 26 allow the transmission of electrical signals. The insulated conducting pathways 1130, 1150 have portions extending in one or more layers, and are aligned at the layer interfaces, allowing the conducting of electrical signals through the MEMS chip 1100. Some of the insulated conducting pathways connect the one or more transducer to first cap MEMS-electrical contacts, part of a first set 1124 of contacts. These insulated conducting pathways are referred as first insulated conducting pathways 1130. They conduct electrical MEMS signals between the transducer(s) 1170 and the first cap MEMS-electrical contacts of said first set 1124. More specifically, insulated conducting pathways 1130 connect electrodes, leads and/or MEMS structures of the transducers 1170 to the first cap MEMS-electrical contacts 1124. Other insulated conducting pathways extend through the entire thickness of the single MEMS chip 1100, i.e. through the first cap layer 1120, through the central MEMS layer 1160 and through the second cap layer 1140. These insulated conducting pathways connect a second set of first cap MEMS-electrical contacts 1126 to some of the second cap MEMS-electrical contacts 1144. They are referred to as second insulated conducting pathways 1150, and serve to conduct auxiliary signals, such as power or digital signals, through the MEMS chip 1100.

The second insulated conducting pathways 1150 provide an isolated pathway between the metallization and bond pads on the first cap layer 1120 and bond pads on the second cap layer 1140, to pass signals from an IC chip 1200, through the MEMS chip 1100, to another IC chip or to a PC board.

Still referring to FIGS. 8A and 8B, the integrated MEMS system 1000 also includes a single IC chip 1200. The IC chip 1200 is typically an application-specific integrated circuit (ASIC) chip, fabricated using complementary metal-oxide-semiconductor (CMOS) technology; but other types of ICs are possible. The IC chip 1200 includes MEMS signal processing circuitry 1240 operatively connected to the first insulated conducting pathways 1130, to process the electrical MEMS signals of the one or more transducers 1170. The IC chip 1200 also includes auxiliary signal processing circuitry 1260, operatively connected to the second insulated conducting pathways 1150, to process the auxiliary signals, and to provide additional system functions. The management functions performed by the IC can include interpretation of the sensor data, compensating for variations in sensor response due to temperature or other environmental variations, microcontroller management of system timing and functions, memory for storage of data such as calibration constants, sensor interpretation constants, and measured data, and wired and unwired data I/O interfaces to external devices such as drone or autonomous vehicles.

The MEMS signal processing circuitry 1240 manages data signals to and from the MEMS transducer 1170. It controls and provides the analog drive and feedback signals required by the transducer; controls the timing of the signal measurements; amplifies, filters, and digitizes the measured signals; and analyses and interprets the incoming MEMS signals from the transducers 1170 to calculate different parameters, such as angular acceleration, or ambient pressure. The MEMS signal processing circuitry 1240 typically includes at least A/D and D/A converters, power, a system controller, a memory, a calibration and composition module, and a data analysis module.

The auxiliary signal processing circuitry 1260 processes signals other than those required strictly to operate the MEMS transducer and output the measured MEMS signals. It can also provide additional system functions, such as monitoring sensor activity to minimize power usage, transmit and receive data wirelessly, receive and interpret GPS signals, integrate additional data from other sensors or GPS for calibration or performance improvements, use the measured data to calculate additional system parameters of interest or to trigger other system activities. When fully utilized the auxiliary signal processing circuitry 1260 allows the integrated 3D system 1000 to control, perform, and analyze the measurements from the integrated MEMS sensor; act as a sensor hub between the 3DS system chip, other attached external sensors, and a larger external system such as a cell phone, game controller, or display; and integrate all the data to make decisions or provide input to the larger system since it can receive, process and send signals other than MEMS signals, from/to a PCB board for example. The MEMS chip also acts as a “smart” interposer between the PCB and the IC chip. Digital and/or analog signals can transit trough the MEMS chip to be processed by the auxiliary circuitry 1260, to be used by the MEMS transducers 1170 (for power signals for example), and can be transmitted back through the MEMS chip, or transmitted wirelessly.

The IC chip 1200 thus includes IC-electrical contacts, bump bonded to the MEMS-electrical contacts of the first cap layer 1120. The IC-electrical contacts are grouped in first and second sets of 1228, 1230, respectively bump bonded to the first and second sets 1124, 1126 of first cap MEMS-electrical contacts. It other words, the set 1128 of IC-electrical contacts are connected to the set 1124 of MEMS-electrical contacts, thereby connecting the first insulated conducting pathways 1130 to the MEMS signal processing circuitry 1240. The set 1230 of IC-electrical contacts are connected to the set 1126 of MEMS-electrical contacts, connecting the second insulated conducting pathways 1150 to the auxiliary signal processing circuitry 1260. Typically, the MEMS-electrical contacts of the first and second cap layers are bond pads.

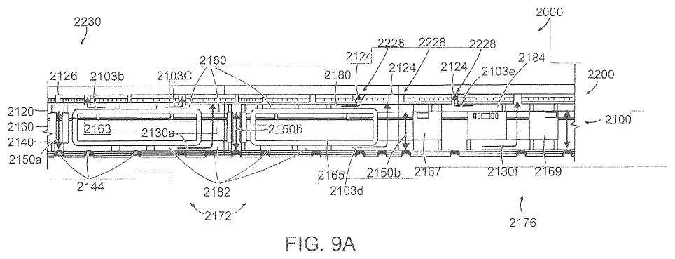

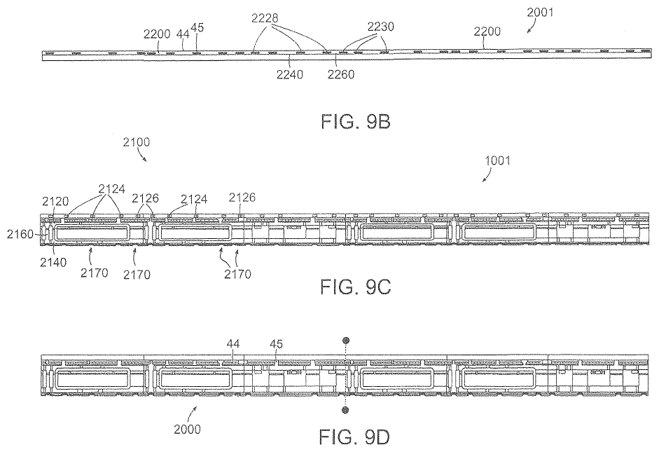

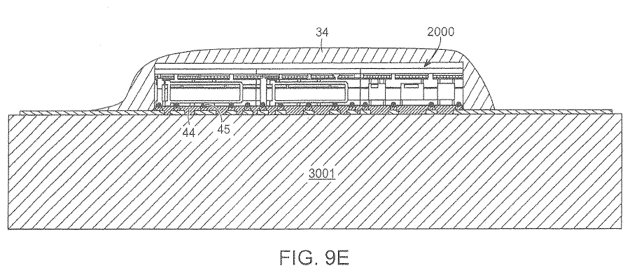

Referring to FIG. 9A, another possible embodiment of an integrated MEMS system 2000 is shown. The exemplary 3DS MEMS chip 2100 is a hermetically sealed 9 degree-of-freedom (DOF) MEMS sensor chip, which includes a 6 DOF inertial sensor 2172 to measure x, y, and z acceleration and angular velocity and a 3 axis magnetometer 2176, all monolithically fabricated in the MEMS chip 2100.

The 6 DOF inertial sensor 2172 senses three axes of linear acceleration and three axes of angular rate. The 6 DOF inertial sensor 2172 includes first and second sets of electrodes 2180, 2182, respectively provided in the first and second cap layers 2120, 2140. One or several proof masses 2163, 2165 can be patterned in the central MEMS layer 2160, the first and second sets of electrodes 2180, 2182 forming capacitors with the proof mass(es). In FIG. 9A, only two proof masses 2163, 2165 are visible, but the 6 DOF inertial sensor 2172 can include more proof masses. The ultimate resolution of MEMS inertial sensors is set over short averaging times (<1 sec) by the noise density and over longer averaging times by the bias stability, which is roughly proportional to the noise density. The IMU noise density consists of two parts: an electrical noise density arising largely from the integrated circuit and a mechanical noise density arising from the MEMS sensor. A large MEMS sensor sensitivity, which is proportional for a gyroscope to the Coriolis force 2MωΩ (where M is the mass, ω is the drive frequency, and Ω is the angular rate), or for an accelerometer to the linear force Ma (where M again is the mass and a is the acceleration), minimizes IC noise. The thermal noise of the MEMS sensor itself is inversely proportional to the mass. So a large mass is key to reducing overall noise. The 6 DOF inertial sensor 2172 has large proof masses 2163, 2165 and sense capacitors 2180 hermetically vacuum sealed at the wafer level. It is important to keep MEMS sensor area small for most applications, so the disclosed sensor system maximizes the inertial mass by increasing its thickness. Using the disclosed architecture, the inertial mass is typically 400 μm thick but can range from 100 μm thick to 1000 μm thick, as compared to other MEMS inertial sensors which are 40 μm thick or less. The large proof mass is typically fabricated in a Silicon-on-Insulator (SOI) wafer having a handle which can be 100-1000 μm thick, a buried oxide layer 1-5 μm thick, and a single crystal silicon (SCS) device layer that is 1-20 μm thick. The bulk of the proof mass is etched in the handle wafer using Deep Reactive Ion Etching (DRIE) of silicon. Alternatively, the proof mass can be formed with a thick SCS device layer in the range of 20-100 microns for certain applications, for example.

The mass of the proof thus can be designed anywhere in the range of 0.1 to 15 milligrams by adjusting the lateral dimensions (0.5 mm to 4 mm, for example, or having an area in a range of 1-3 mm²), thickness as described herein, or both. The springs which support the proof mass and the top of the mass are etched in the SCS device layer. The resonant frequency (√(k/M) can be tuned separately by adjusting the spring constant k through the thickness of the device layer and the width and length of the spring. The spring constant k is proportional to wt³/L³, where w, t, and L are the width, thickness, and length respectively of the spring. Lower frequencies (long, thin springs) around 1000 Hz are desirable for the accelerometer, while higher frequencies (short, wide springs) are desirable for the gyroscopes. Generally, resonant frequencies between 500 Hz and 1500 Hz are used for a variety of applications. The capacitor electrodes and gaps are etched into the faces of the cap wafers which are bonded to the MEMS wafer. The gaps are typically 1-5 μm thick providing sense capacitors which can range from 0.1 to 5 picofarads. Further details concerning fabrication and operation of MEMS transducer devices can be found in U.S. patent application Ser. No. 14/622,619, filed on Feb. 13, 2015 (now U.S. Pat. No. 9,309,106) and U.S. patent application Ser. No. 14/622,548, filed on Feb. 13, 2015, the above referenced patent and applications being incorporated herein by reference in their entirety.

For industrial and tactical grade applications, which include high resolution motion capture and personal navigation, the thick mass and as-fabricated high quality factor (˜5000) produce a gyroscope noise density ranging from 0.005 deg/hr to 0.1 deg/hr. The resulting gyroscope bias stability ranges between 0.05 deg/hr, and 1 deg/hr. This noise is lower than many fiber optic and ring laser gyroscopes that cost thousands of dollars more. Because existing consumer-grade MEMS gyroscopes use inexpensive packaging and have small inertial masses and sense capacitors, they have low quality factors and low angular rate sensitivities leading to large noise densities on the order of 1 deg/hr and bias stability on the order of 10 deg/hr., inadequate for tactical and navigational use. Similarly, the accelerometer has a noise density ranging from 3 micro-g/Hz to 30 micro-g/Hz and bias stability ranging from 0.5 micro-g to 10 micro-g, much lower than consumer-grade accelerometers. The platform also allows the addition of other sensor types such as pressure sensors and magnetometers (shown here a 3 axis magnetometer 2176) to improve overall accuracy through sensor data fusion. The sensor data can be processed by data processor circuits integrated with the MEMS chip and IC chips as described herein, or by external processors. For navigation grade applications, which include high performance unmanned vehicle and autonomous navigation, two masses can be combined in an antiphase drive mode to not only increase the effective mass by a factor of 2, but to increase the quality factor by reducing mechanical energy losses. This approach can produce a gyroscope noise density ranging from 0.002 deg/hr to 0.01 deg/hr and bias stability ranging between 0.01 deg/hr, and 0.1 deg/hr, for example, thereby providing improved gyroscope performance.

The MEMS chip 2100 includes first and second insulated conducting pathways, 2130, 2150, similar to those described previously. The first insulated conducting pathways 2130 connect the MEMS electrodes 2180, 2182 to a first set 2124 MEMS-electrical contacts, on the first cap layer 2120. The second insulated conducting pathways 2150 extend through the entire thickness of the MEMS chip 2100, allowing the transmission of auxiliary (or additional) signals through the MEMS chip 2100. The second insulated conducting pathways 2150 connect a second set 2126 of MEMS-electrical contacts of the first cap layer 2120 to some of the MEMS-electrical contacts 2144 of the second cap layer 2140. For clarity, only some of the first insulated conducting pathways are indicated in FIG. 9A, such as pathways 2130a, 2130d extending between the second cap electrodes 2182 and MEMS-electrical contacts 2124 of the first cap layer 2120, and pathways 2130b and 2130c, connecting first cap electrodes 2180 patterned in the first layer 2120 with MEMS-electrical contacts 2126 of the same layer 2120. Similarly, only some of the second insulated conducting pathways are indicated in FIG. 9A, such as pathways 2150a and 2150b, connecting electrical contacts 2124, 2126 in the first cap layer 2120 with electrical contacts 2144 in the second cap layer 2140.

Referring again to FIG. 9A, the single MEMS chip can also include transducer(s) which are non-inertial sensor(s). Examples of possible non-inertial sensors include pressure sensors, magnetometers, thermometers, microphones, micro-fluidic and micro-optic devices. Other types of non-inertial sensors are also possible. The non-inertial sensor includes non-inertial electrodes patterned in at least one of the first and second layers. The non-inertial sensor also includes at least one MEMS structure patterned in the central MEMS layer, which can include non-inertial electrodes. Example of MEMS structures in a non-inertial sensor include membranes, such as those used in pressure sensor, microphone or magnetometer. Some of the first insulated conducting pathways in the MEMS chip connect the non-inertial electrodes to at least some of the first cap MEMS-electrical contacts, so as to transmit signals from the non-inertial electrodes to the bond pads of the first layer of the MEMS chip, which is in turn connected to the IC chip.

In the embodiment of FIG. 9A, the non-inertial sensor is a three-axis magnetometer 2176, which can be used to improve the accuracy of the inertial sensor 2172. The IC-electrical contacts 2228, 2230 (such as IC I/O bond pads) of the single IC chip 2200 are bonded directly to the MEMS-electrical contacts 2126, 2124 (such as MEMS I/O bond pads) of the single MEMS chip 2100, reducing electrical noise and eliminating wire bonding. The magnetometer 2176 includes non-inertial electrodes, such as electrode 2184, and resonant membranes 2167, 2169.

Analog data can be communicated between the MEMS sensors 2172, 2176 and the IC chip 2200 at an analog-to-digital converter (ADC) input/output mixed signal stage of the IC chip 2200. The MEMS signals generated by the sensors 2172, 2176 are analog signals, so they are converted to digital by the ADC to be further processed in the digital CMOS portion of the IC chip 2200. The data processing of the MEMS signals by the IC chip 2200 can include sensor calibration and compensation, navigational calculations, data averaging, or sensor data fusion, for example. System control can be provided by an integrated microcontroller which can control data multiplexing, timing, calculations, and other data processing. Auxiliary (or additional) signals are transmitted to the IC chip via additional digital I/O. The IC chip 2200 includes auxiliary signal processing circuitry, such as for example wireless communications or GPS (Global Positioning System) functionality. The GPS data can also be used to augment and combine with MEMS sensor data to increase the accuracy of the MEMS sensor chip 2100. These are examples only, and more or fewer functions may be present in any specific system implementation. As can be appreciated, in addition to providing the analog sensing data via the MEMS signals, the MEMS chip 2100 can also provide an electronic interface, which includes power, analog and digital I/O, between the MEMS system 2000 and the external world, for example, a printed circuit board in a larger system.

As per the embodiment shown in FIG. 9A, the single MEMS chip 2100 is integrated into the 3D MEMS System 2000 (3DS) and acts as both an active MEMS device and an interposer for signal distribution. One possible use of the 3DS architecture includes wafer-scale integration of the MEMS and IC, as schematically represented in FIGS. 9B to 9F.

FIG. 9B is a schematic representation of an IC wafer 2001. An IC wafer can be constructed using any one of CMOS, Gallium Arsenide (GaAs) or other III-V compounds, Indium Phosphide (InP) or other II-VI compounds, Silicon Carbide, or other technologies. The IC wafer 2001 includes several IC chips 2200. Each IC chip includes MEMS signal processing circuitry 2240 and auxiliary processing circuitry 2260, formed by IC transistors. The functionalities included in the IC chip can include GPS, RF, logic and/or memory. The IC wafer 2001 also includes inter-level metal interconnects, and IC-electrical contacts, typically bond pads. The IC-electrical contacts are grouped in first and second sets of contacts 2228, 2230: the IC-contacts of the first set 2228 are designed to connect with MEMS-electrical contacts linked to the first insulated pathways, and the second set 2230 are designed to connect with MEMS-electrical contacts linked to the second insulated pathways.

FIG. 9C is a schematic representation of a multi-wafer stack 1001, including several single MEMS chips, such as MEMS chip 2100 of FIG. 9A. The ASIC wafer 2001 of FIG. 9B and the MEMS multi-wafer stack 1001 of FIG. 9C can be fabricated in separate MEMS and IC foundries, in order to take advantage of existing processes to minimize cost and increase yield. In this example, two IC chips and two MEMS chips are shown, before dicing.

During the fabrication process of the MEMS stack 1001, channels are etched in the first and second layers to define the borders of electrodes, leads, and feedthroughs on the inward-facing surfaces of the first and second silicon wafers. The channels are then lined, or filled, with an insulating material such as thermal oxide or CVD (Chemical Vapor Deposition) silicon dioxide. Both sides of the central MEMS wafer, which is typically an SOI wafer, are patterned with electrodes and MEMS structures, such as membranes and proof masses. Conductive shunts are formed in specific locations in the buried oxide layer, to allow electrical signals to pass from the device to the handle layer, through what will become the insulated conducting pathways. The central and cap MEMS wafers are also patterned with respective frames enclosing the MEMS structures. The various conducting pathways required by the device are constructed by aligning feedthrough structures on each level. The portion of the insulated conducting pathways in the central MEMS wafer can be isolated either by insulator-filled channels or by etched open trenches since the MEMS wafer is completely contained within the stack and the isolation trenches do not have to provide a seal against atmospheric leakage like the cap trenches. The frames are also bonded so as to form hermetically sealed chambers around the MEMS structures. After the wafer stack 1001 is assembled, the cap wafers are ground and polished to expose the isolated conducting regions.

FIGS. 9B-9D illustrate a preferred way of bonding the MEMS and IC wafer 1001, 2001. An underfill 44 is applied to the top side CMOS wafer 2001 and patterned to expose the IC electrical contacts (bond pads in this case). Solder bumps 45 are deposited on the bond pads. The IC wafer 2001 is flipped and aligned to the MEMS wafer 1001, such that the IC bond pads and solder bumps are aligned to the bond pads of the first cap wafer. The IC wafer 2001 is bonded to the MEMS wafer 1001 using temperature and pressure to produce a MEMS integrated system wafer.

The bonded 3DS wafer can now be diced (along the dotted lines in FIG. 9D) into individual integrated MEMS system components, also referred as 3D System on Chip (3DSoC). The exposed side of the IC chip is protected by an oxide passivation layer applied on the silicon substrate, and the MEMS/ASIC interface is protected by an underfill 44. The diced chips 2000 can be treated as packaged ICs and the bottom cap bond pads provided on the second cap can be bump bonded to the bond pads on a PCB 3001, with no additional packaging, as shown in FIG. 9E. A PCB underfill 44 is applied to the PCB and patterned to clear contacts over the PCB bond pads. Solder bumps 45 are applied to the exposed PCB bondpads and the diced 3DS component chip 2000 can be flip chip bonded to the PCB 3001. If additional moisture protection is desired, a polymeric encapsulant or other material 34 can be applied. No additional capping or bond wires are required.

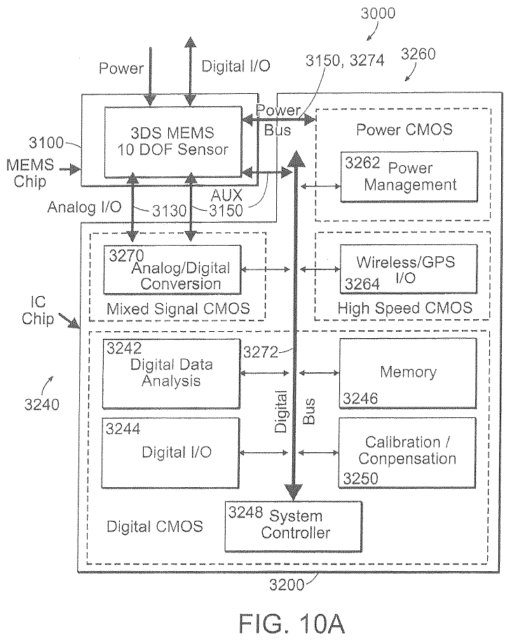

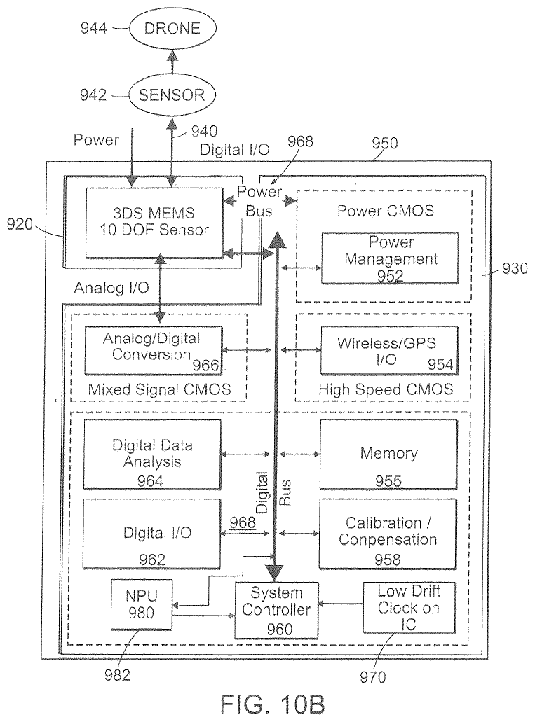

FIG. 10A is a block diagram representing a preferred embodiment of an integrated MEMS system, in this case a ten degree of freedom (10-DOF) IMU system 3000. Note that a 6 degree of freedom (6 DOF) system including three accelerometers, one or more gyroscopes and additional sensors as described previously herein can also be fabricated using the circuit components configured in FIG. 10A. The system 3000 includes a 10-DOF single MEMS chip 3100, and a single IC chip 3200, the MEMS chip and the IC chip having architecture similar to that described for the system 2000 of FIG. 9A. The MEMS chip 3100 comprises top cap, central MEMS and bottom cap layers, with transducers patterned in the layers. The transducers can include a three-axis accelerometer (or three accelerometers), gyroscope and magnetometer, as well as a pressure sensor. First and second insulated conducting pathways 3130, 3150 are formed within the MEMS layers to transmit MEMS-signals and auxiliary signals. The insulated conducting pathways 3130, 3150 connect to MEMS-electrical contacts on the first and/or second cap layers. A single IC chip 3200 is bump bonded to the first layer of the MEMS chip, and includes MEMS-signal processing circuitry 3240, and auxiliary-processing circuitry 3260. The MEMS-signal processing circuitry processes the transducers' I/O signals, i.e. signals generated by the transducers and/or signals for controlling the transducers. The auxiliary-processing circuitry 3260 processes auxiliary signals, i.e. signals transiting through the second insulating pathways of the MEMS chip 3100, such as signals for powering the transducers and/or digital signals for controlling the transducers.

In the present embodiment, the MEMS-signal processing circuitry 3240 includes specialized digital CMOS circuitry modules such as digital data analysis circuitry 3242, digital input/output circuitry 3244, memory 3246, a system controller 3248 and calibration/compensation circuitry 3250. The auxiliary signal processing circuitry 3260 includes power management circuitry 3262, and high speed CMOS circuitry 3264 which may include wireless and/or GPS I/O modules. The digital components in the MEMS-signal processing circuitry 3240 and in the auxiliary signal processing circuitry 3260 communicate over a digital bus 3272.

Since the transducers operate using analog signals, the IC chip 3200 includes mixed-signal CMOS circuitry 3270 to allow the IC chip 3200 to interface with the input and output of the MEMS sensor 3100. The mixed-signal CMOS circuitry 3270 includes an ADC to convert analog signals generated by the MEMS chip 3100 into digital signals for processing by the MEMS signal processing circuitry 3240. The mixed-signal CMOS circuitry 3270 also includes a DAC for converting digital signals received from the MEMS-signal processing circuitry 3240 and/or auxiliary signal processing circuitry 3260 into analog signals for controlling the MEMS chip 3100. The mixed-signal CMOS circuitry 3270 communicates with the other digital components of the IC chip 3200 over the digital bus 3272.

The 3DS sub-systems are distributed among these various circuits. For example, consider a 3DS Inertial Navigation Unit (INU) based on a 10 DOF MEMS sensor consisting of a 6DOF inertial sensor measuring angular rate and acceleration, a pressure sensor, and a 3DOF magnetometer as illustrated in FIG. 10A. Part of the 3DS system can act as a system sensor hub when digital request for a position/attitude reading from a larger system comes in through the PCB board Digital I/O leads or wireless I/O 3264 which requires high-speed or RF CMOS running at higher clock rates than the memory or logic sections. The request travels through the Digital Bus 3272 and Digital I/O section 3244 to the system controller 3248. The system controller 3248 would provide the clock signals to trigger and time the measurements of each of the 3 angular rate, 3 acceleration, 3 magnetic field, and 1 pressure reading. The analog/digital section 3270 provides the DC bias and gyroscope drive signals required to measure the capacitances of the various sensors, as well as amplify the signals and convert them into digital data representing angular rate, acceleration, magnetic field, and pressure. The digital analysis circuitry 3242 can take the raw digital sensor data and using algorithms and constants stored in memory 3246 calculate real-time values of acceleration and angular rate (IMU output), as well as pressure and magnetic field. However, if an inertial navigation output (e.g. position and attitude) are required the digital data analysis section 3242 will perform additional calculations to integrate the 6 DOF data with the pressure and magnetic field data along with external sensor readings (such as GPS) to provide instantaneous position and attitude. These “sensor fusion” algorithms and constants can be stored in memory 3246. Finally the results are output through the digital I/O section 3244 through the digital bus either through the MEMS chip to the PCB board or via RF wireless radio with the 3DS chip acting again as a sensor hub to communicate with the larger system.

As illustrated, the IC 3200 interfaces with the MEMS chip 3100 via the conducting pathways 3130 and 3150. The first conducting pathways 3130 conduct the transducers' I/O signals and are therefore analog channels. The first pathways 3130 therefore travel through the mixed-signal CMOS circuitry 3270 interface before reaching the digital bus 3272. The second conducting pathways 3150 conduct the auxiliary signals. Since the auxiliary signals could be analog or digital, they may take different paths into the IC chip 3200 depending on their function. For example, an analog auxiliary signal could interface with the IC chip 3200 via the mixed-signal CMOS circuitry 3270, while a digital signal could interface directly with the digital bus 3272. If a second conducting pathway 3150 is carrying a power signal, it could act as a power bus 3274 and interface directly with the power management circuitry 3262, for example, with the power management circuitry 3262 also being connected to the digital bus 3272 for communicating digital data.

Illustrated in FIG. 10B is a further example of a IC chip 950 configured for processing of inertial sensor data that can further include feedback control of sensor operation or that can also be configured to control operations of an autonomous vehicle such as a drone, a satellite or other propulsion system using sensed inertial data. A clock 970 controls timing of control and signal processing operations on the IC chip 950. System controller 960 sends control signals for operations of IMU operations. The IC chip 950 is connected of a MEMS inertial sensor 920 as well as external sensors 942 and one or more devices 944 which operate in response to inertial sensor data generated by inertial sensor 920. The IC Chip can be connected to a neural processing unit (NPU) 980 that can be mounted on a circuit board with the IC chip or fabricated in a system on chip design. The NPU 980 can comprise a logic circuit such as an FPGA, and application specific integrated circuit (ASIC) or a graphics processing unit (GPU) that performs computational processing of inertial sensor data form the inertial sensor at 982, or can access data stored in memory 956.

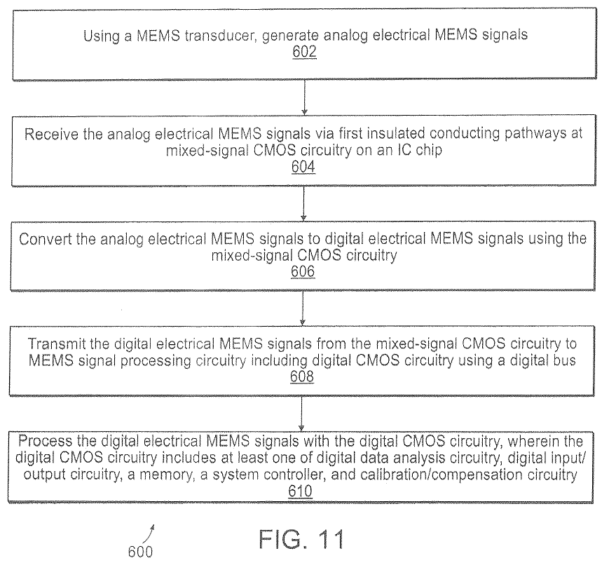

Referring to FIG. 11, a process flow diagram is illustrated that describes a method 600 of operating a MEMS transducer device. Analog electrical MEMS signals are generated using a MEMS transducer (step 602). The analog electrical MEMS signals are received via first insulating conducting pathways at mixed-signal CMOS circuitry on an IC chip (step 604). The mixed-signal CMOS circuitry converts the analog electrical MEMS signals to digital electrical MEMS signals (step 606). The digital electrical MEMS signals are transmitted from the mixed-signal CMOS circuitry to MEMS signal processing circuitry including digital CMOS circuitry using a digital bus (step 608). The digital CMOS circuitry processes the digital electrical MEMS signals (step 610). The digital CMOS circuitry includes at least one of digital data analysis circuitry, digital input/output circuitry, a memory, a system controller, and calibration/compensation circuitry.

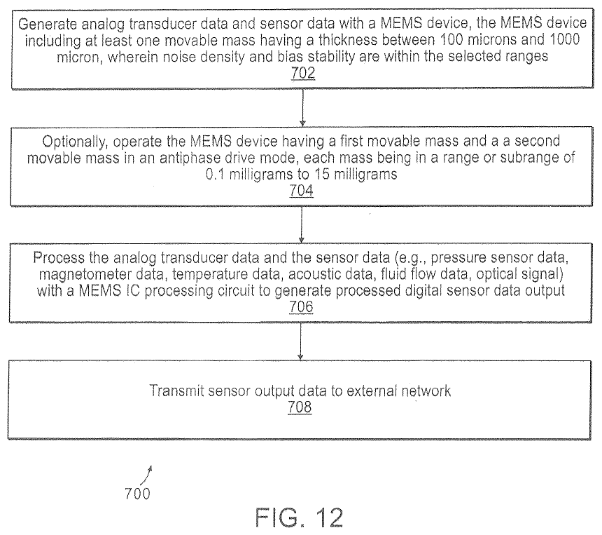

Referring to FIG. 12, a process flow diagram illustrated that describes a method 700 of operating a proof mass MEMS device in accordance with preferred embodiments of the invention. Transducer data and sensor data are generated with a MEMS device (step 702). The MEMS device includes at least one moveable mass having a thickness between 100 microns and 1000 microns. The mass area and thickness are chosen to provide noise density and bias stability values within selected ranges. Optionally, the MEMS device having a first moveable mass and a second moveable mass is operated in an antiphase drive mode (step 704). A plurality of masses are selected to reduce noise. The transducer data and the sensor data are processed with a MEMS IC processing circuit to generate digital sensor data output (step 706) as described herein. The device can then transmit to sensor output data by wired or wireless transmission to an external application by a communication network.

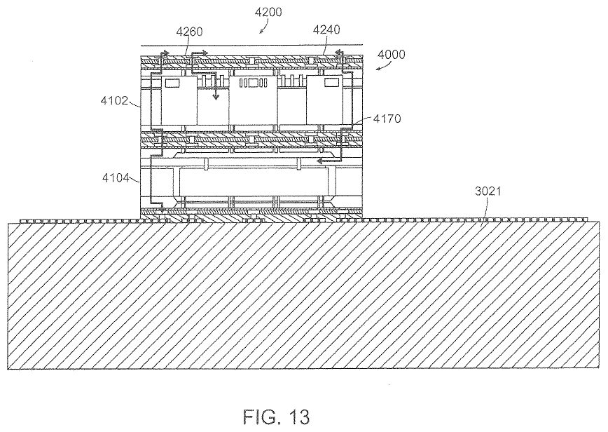

To reduce the final device footprint area, an alternative architecture of the MEMS integrated system enables multiple single MEMS wafers to be stacked vertically, to form the 3DS MEMS wafer. In one embodiment, an IC-wafer bonded to a multi-wafer 3DS MEMS consisting of two MEMS wafers of different device types, can be stacked and bonded to each other. By aligning the first and second insulated conducting pathways (also referred as 3DTCVs), MEMS and auxiliary signals can be routed through the entire stack of MEMS and ASIC chips, simplifying power bussing and minimizing lead routing between the various MEMS functions and the electronics. FIG. 13 shows the diced 3DS component 4000 consisting of a stack of an IC chip 4200 and two single MEMS chips 4102, 4104 bump bonded to a printed circuit board 302. In this case, the second layer of the single MEMS chip 4102 is bump bonded to the first layer of the additional single MEMS chip 4104. The second insulated conducting pathways 4150′ of the additional single MEMS chip 4104 is electrically connected to at least some of the second insulated conducting pathways 4150 of the first single MEMS chip 4102, to conduct auxiliary signals through the first and the additional single MEMS chip, to the auxiliary-signal processing circuitry of the IC chip 4200. The interconnected second insulated conducting pathways of the MEMS chips 4102 and 4104 are configured to send auxiliary signals from the PCB up to the IC chip for processing, without requiring any wire-bonding.

MEMS signals for the MEMS chip 4104 can also transit through the MEMS chip 4102, up to the IC chip 4200. The first MEMS chip 4102 comprises a third set of first cap MEMS-electrical contacts and third insulated conducting pathways 4170 to connect the first cap MEMS-electrical contacts of the third set to at least some of the second cap MEMS-electrical contacts of the second cap layer of MEMS chip 4102, through the first cap layer, the central MEMS layer and the second cap layer. These third insulated conducting pathways 4170 are electrically connected to the MEMS signal processing circuitry 4240 of the IC chip 4200, and are electrically connected to insulated conducting pathways 4130′ of MEMS chip 4104. The MEMS signal processing circuitry 4240 can thus process the electrical MEMS signals of the first and of said at least one additional single MEMS chips. The MEMS-signal processing circuitry 4240 can thus process MEMS-signals from both MEMS chips 4102 and 4104. Of course, while in the embodiment shown in FIG. 13 there are two MEMS chips, it is possible to stack more than two MEMS chips of the same or of different types. An integrated MEMS system component can thus include a first single MEMS chip and additional single MEMS chips, stacked vertically.

For embodiments employing a control system utilizing an inertial measurement unit (IMU) that includes a controller, a processor, and a memory that causes the processor to receive, from one or more inertial and/or non-inertial sensors as described previously herein, sensor signals and convert the sensor signals into many the components of a measurement vector. The processor can be programmed to determine a first state vector using IMU Kalman filter, update a first subset of components the system state vector, determine a second state vector using a spatial positioning Kalman filter, update a second subset of components of the system state vector based on the second state vector, determine a third state vector using a system Kalman filter, update a third subset of components of the many components of the system state vector based on the third state vector, and control system operating parameters based on at least one of the first state vector, the second state vector, the third state vector, and the system state vector.

In another embodiment, a tangible, non-transitory, computer-readable medium stores instructions executable by a processor, such that the instructions cause the processor to receive, from one or more inertial and/or non-inertial sensors as previously describe herein, sensor signals and convert the sensor signals into components of a system measurement vector. The instructions cause the processor to determine a first state vector using an inertial measuring unit (IMU) Kalman filter based on the system measurement vector and a system state vector, update a first subset of components of many components of the system state vector based on the first state vector, determine a second state vector using a spatial positioning Kalman filter using the system measurement vector and the system state vector, update a second subset of components of the many components of the system state vector based on the second state vector, determine a third state vector using a system Kalman filter based on the measurement vector and the system state vector, update a third subset of components of the many components of the system state vector based on the third state vector; and control an operation or movement based on at least one of the first state vector, the second state vector, the third state vector, and the system state vector.

The use of Kalman filters for each of the inertial sensors can simplify computational complexity and improve processing speed. Thus, in embodiments employing three accelerometers, for example, three Kalman filter are used to process the respective accelerometer outputs. Other sensors including magnetometers, pressure sensors, and optical sensors or cameras can also be filtered as described herein to periodically update the system state vector. A spatial positioning device can be include, such as a global positioning system (GPS) or a global navigation satellite system (GNSS), for example, wherein the device generates position data used with filtered sensor data to enhance IMU operation. In certain embodiments, the spatial positioning device can be configured to determine the position of the system relative to a fixed point within the field (e.g., via a fixed radio transceiver). Accordingly, the spatial positioning device can be configured to determine the position of the system relative to a fixed global coordinate system (e.g., via the GPS) or a fixed local coordinate system. In certain embodiments, a first transceiver is configured to broadcast a signal indicative of the position of the system to the transceiver of a base station.

The processor executes software, such as software implementing the Kalman filters described herein. The processor can include multiple microprocessors, one or more general-purpose microprocessors, and/or one or more application specific integrated circuits (ASICS), one or more field programmable gate array devices (FPGAs) or some combination thereof. In some embodiments, the subject matter described herein can be performed by a tangible, non-transitory, and computer-readable medium having instructions stored thereon. Commercial software products are available from Mathworks Inc., Natick, MA that incorporate Kalman filters to estimate the state of systems using inertial sensors using the Matlab® and Simulink® products, for example.

The following comprise the expressions for an iterated, extended Kalman filter as follows:

### Time Update Prediction (Global):

### State Estimation Propagation

$${\hat{x}}_{k \vert k - 1} = {F}_{k , k - 1} {\hat{x}}_{k - 1 \vert k - 1} \qquad ( 1 )$$

### Error Covariance Propagation

$${P}_{k \vert k - 1} = {F}_{k \vert k - 1} {P}_{k - 1 \vert k - 1} {F}_{k , k - 1}^{T} + {Q}_{k , k - 1} \qquad ( 2 )$$

### Measurement Update (Global+Local):

### Initialization for State Estimation

$${\hat{x}}_{k \vert k}^{0} = {\hat{x}}_{k \vert k - 1} \qquad ( 3 )$$

### State Estimate Update

$${\hat{x}}_{k \vert k}^{i + 1} = {\hat{x}}_{k \vert k - 1}^{i} + {K}_{k}^{i} [ {z}_{k} - h ( {\hat{x}}_{k \vert k}^{i} ) - {H}_{k} ( {\hat{x}}_{k \vert k} ) ( {\hat{x}}_{k \vert k - 1} - {\hat{x}}_{k \vert k}^{i} ) ] , i = 0 , 1 , 2 , \qquad ( 4 )$$

### Kalman Gain Update

$${K}_{k}^{i} = {P}_{k \vert k - 1} {H}_{k}^{T} ( {x}_{k \vert k}^{i} ) [ {H}_{k} ( {x}_{k \vert k}^{i} ) {P}_{k \vert k - 1} {H}_{k}^{T} ( {x}_{k \vert k}^{i} ) + {R}_{k}^{- 1} ] \qquad ( 5 )$$

### Error Covariance Update

$${P}_{k \vert k}^{i + 1} = {P}_{k \vert k - 1} - {K}_{k} ( {\hat{x}}_{k \vert k}^{i} ) {H}_{k} ( {\hat{x}}_{k \vert k}^{i} ) {P}_{k \vert k - 1} \qquad ( 6 )$$

In the above, x is the state vector, F is the state transition matrix, P is the covariance matrix, Q is the covariance of dynamic disturbance noise, R is the covariance of measurement noise, H is the measurement sensitivity matrix, and K is the Kalman gain. The index “i” is used for iteration and k is the time related index. As can be determined from equations (1)-(6), for a local iterated, extended Kalman filter implementation, only measurement equations (4)-(6) are updated during iteration. For an IMU with an iterated, extended Kalman filter implementation, all the inertial sensor data is used. Due to the back propagation of the state estimate, a global iterated, extended Kalman filter implementation is utilized, including use for gyroscope alignment, for example. However, in preferred implementations of the devices described herein, one or more gyroscopes and/or accelerometers can be implemented by fabrication on the same wafer, or by stacking chips made using the same or similar photolithographic process steps to minimize alignment disparities. The basic formulas for the global iterated, extended Kalman filter implementation uses both time approximation equations (1)-(2) and measurement equations (4)-(6) that are periodically updated. When convergence is achieved, iteration can be stopped.

During iteration, residues in the measurement equations can be used to determine the error states which can indicate error reduction. Additionally, a Kalman gain associated with each Kalman filter is factored when determining a size of the step to the next error state determination. Specifically, a Kalman filter reduces gyroscope alignment time by iterating both time updating equations and measurement updating equations, for example. Due to lower noise levels for the MEMS devices described herein compared to data from various inexpensive MEMS based inertial systems, the time step for the extended Kalman filter can be adapted for specific applications. A smaller time step may be used to measure the nonlinearity for the sensor data during calibration.

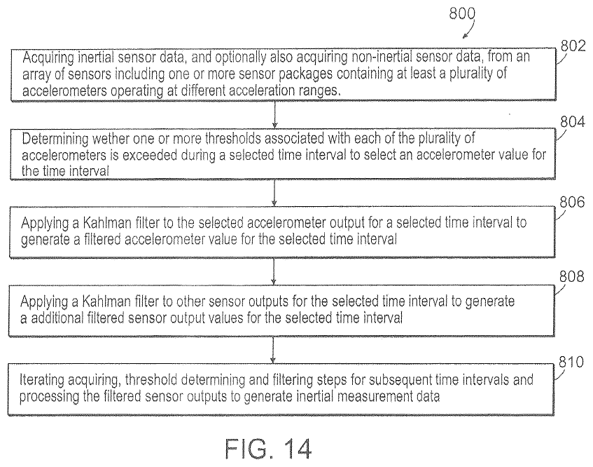

As illustrated in the process flow diagram 800 of FIG. 14, the method comprises acquiring 802 system sensor data including data from at least a plurality of accelerometers in a sensor package wherein the plurality of accelerometers operate at different acceleration ranges. The sensor circuit determines 804 whether one or more thresholds associated with each of the accelerometers is exceeded during a selected time interval to select an accelerometer output value for the selected time period. A Kalman filter is applied 806 to the selected accelerometer value for the time period to generate a filtered accelerometer value for the time period. If additional sensor values are also processed for the selected time interval, such as gyroscope data, temperature sensor data, pressure data, and/or position data, apply a Kalman filter 808 to the additional sensor outputs during the selected time interval. This sequence of steps is applied iteratively 810 over subsequent time intervals to generate filtered sensor data outputs to generate inertial sensor measurement data for use by an inertial navigation unit, for example. This system provides for fusion of sensor data in accordance with preferred embodiments.

In an alternative embodiment, the Kalman filter is replaced by a neural network implemented in the digital signal processor (3242 in FIG. 10A) or by a Neural Processing Unit (NPU) 980 (FIG. 10B) specifically designed for machine learning (ML) operations. ML is commonly understood to enable the systems' ability to learn and improve decision-making based on experience instead of relying on explicit programming. This approach enables the processing of data without the need for rigorous models. The learning process starts with some combination of observations, data, or instructions. The data is processed to derive patterns that can be used to improve the future operations based on the observations and feedback received by the system. This technique allows systems to learn automatically with minimum human intervention thereby enabling adaptive behavior of the system using iterative computational methods to control processing and operation of the system.

ML allows systems to program themselves and improve their performance through a process of continuous refinement. In conventional systems, data and programs are simply run together to produce the desired output, leaving any problems to be caught or improvements to be made by the programmer. In contrast, ML systems use the data and the resulting output to create a program or model. This program can then be used in conjunction with traditional programming to operate one or more systems including an inertial sensor or systems that employ inertial sensor output to perform motion control operations, for example.

There are several different approaches of ML, each best suited to a particular class of applications. Supervised learning is based on feeding the system with “known” rules and features that represent the relationship of an input (for example, position) with an output (acceleration). In contrast, unsupervised learning only provides the inputs to the system, leaving the ML algorithm(s) to analyze them to discover unique/separable classes and patterns.

Neural processing units are frequently implemented with integrated circuit chips that can include three classes: graphics processing units (GPUs), field programmable gate arrays (FPGAs), and application-specific integrated circuits (ASICs). GPUs were originally designed for image-processing applications that benefited from parallel computation. During 2012, GPUs started seeing increased use for training machine learning systems and by 2017, were dominant. GPUs are also sometimes used for inference, that is, to project a result or output that is utilized. Yet in spite of allowing a greater degree of parallelism than CPUs, GPUs are still designed for general-purpose computing.

FPGAs and ASICs have become more prominent for inference, due to improved efficiency compared to GPUs. ASICs are increasingly used for training, as well. FPGAs include logic blocks (i.e. modules that each contain a set of transistors) whose interconnections can be reconfigured by a programmer after fabrication to suit specific algorithms, while ASICs include hardwired circuitry customized to specific computational tasks or execute algorithms. Leading ASICs typically provide greater efficiency than FPGAs, while FPGAs are more customizable than ASICs and facilitate design optimization as computational methods are adapted for specific applications. ASICs, by contrast, grow increasingly obsolete as new computional methods are developed.

Different neural processing chips may be used for training versus inference, given the various demands on chips imposed by each task. First, different forms of data and model parallelism are suitable for training versus inference, as training requires additional computational steps on top of the steps it shares with inference. Second, while training virtually always benefits from data parallelism, inference often does not. For example, inference may be performed on a single piece of data at a time. However, for some applications, inference may be performed on many pieces of data in parallel, especially when an application requires fast inference of a large number of different pieces of data. Third, depending on the application, the relative importance of efficiency and speed for training and inference can differ. For training, efficiency and speed are both important. For inference, high inference speed can be essential, as many neural processing applications deployed in critical systems (e.g. autonomous vehicles) or with impatient users (e.g. mobile applications for classifying images) require fast, real-time data classification. On the other hand, there may be a ceiling in useful inference speed. For example, inference need not be any faster than user reaction time to a mobile application. Inference chips require fewer research require optimization for fewer computations than training chips. ASICs require less development than GPUs and FPGAs; because ASICs are typically narrowly optimized for specific algorithms, and design engineers consider far fewer variables. To design a circuit meant for only one calculation, an engineer can simply translate the calculation into a circuit optimized for that calculation. But to design a circuit meant for many types of calculations, the engineer must predict which circuit will perform well on a wide variety of tasks, many of which are unknown in advance.

A neural processing chip's commercialization has depended on its degrees of general purpose capability. GPUs have long been widely commercialized, as have FPGAs to a lesser degree. Meanwhile, ASICs are more difficult to commercialize given high design costs and specialization-driven low volume. However, a specialized chip is relatively more economical in an era of slow general-purpose chip improvement rates, as it has a longer useful lifetime before next-generation CPUs attain the same speed or efficiency. In the current era of slow CPU improvements, if an processing chip exhibits a 10-100× speedup, then a sales volume of only 15,000-83,000 can be sufficient to make neural processing chips economical. The projected market size increase for neural processing chips could create the economics of scale necessary to make ever narrower capability ASICs profitable. Neural processing chips come in different grades, from more to less powerful. At the high end, server grade neural processing chips are commonly used in data centers. At the medium-end are PC grade neural processing chips commonly used by consumers. At the low-end, mobile neural processing chips are typically used for inference and integrated into a system-on-chip that also includes a CPU. A mobile system-on-chip needs to be miniaturized to fit into mobile devices. At each of these grades, chip market share increases have come at the expense of non-neural processing chips.

Supercomputers have limited but increasing relevance for neural processing. Most commonly, server grade chips are distributed in data centers and can be executed sequentially or in parallel in a setup called “grid computing.” A supercomputer takes server grade chips, physically co-locates and links them together, and adds expensive cooling equipment to prevent overheating. This improves speed but dramatically reduces efficiency, An acceptable tradeoff for many applications requiring fast analysis. Few current applications justify the additional cost of higher speed, but training or inference for large algorithms is sometimes so slow that supercomputers are employed as a last resort. Accordingly, although CPUs have traditionally been the supercomputing chip of choice, In 2018, GPUs were responsible for the majority of added worldwide supercomputer computational capacity.

There is no common scheme in the industry for benchmarking CPUs versus neural processing chips, as comparative chip speed and efficiency depends on the specific benchmark. However, for any given node, neural processing chips typically provide a 10-1,000× improvement in efficiency and speed relative to CPUs, with GPUs and FPGAs on the lower end and ASICs higher end A neural processing chip 1,000× as efficient as a CPU for a given node provides an improvement equivalent to 26 years of CPU improvements. Gains for GPUs, FPGAs, and ASICs relative to CPUs (normalized at 1×) for DNN training and inference at a given node. GPUs are commercially available from Nvidia Corporation that can be mounted on a printed circuit board implementation of an IMU that can be vertically stacked with inertial sensor devices as described herein for example. Alternatively, an ASIC device can be fabricated in a CMOS circuit layer of a system on chip integrated circuit as described herein.

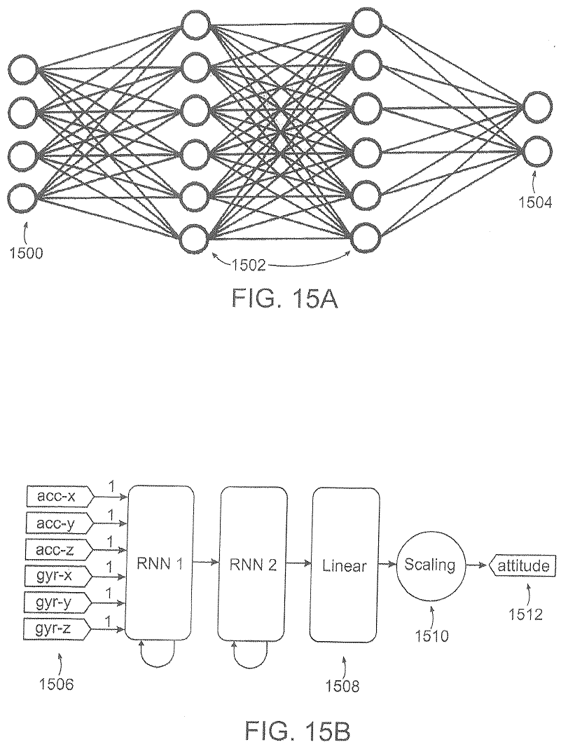

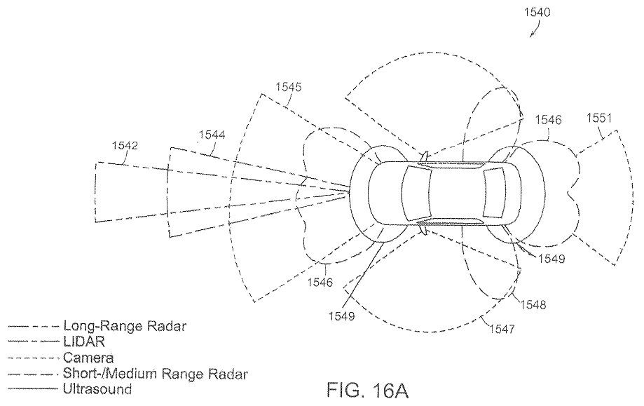

Shown in FIGS. 15A-B is an exemplary embodiment of a neural network configured to process inertial sensor data to correct for cumulative errors that can occur over time and provide for predictive modeling of position and heading for autonomous vehicles, for example. In this example, a recurrent neural network (RNN) comprises input nodes 1500, hidden layers 1502 of the network and output nodes 1504. As shown in FIG. 15B, the input 1506 comprises accelerometer and gyroscope data each acquired over orthogonal x, y and z axes. Two RNN layers process the data followed by a linear layer, and scaling based on unit length to provide attitude data. Further details concerning such an implementation are described inn further detail by Weber et al., Neural Networks Versus Conventional Filters for Inertial-Sensor based Attitude Estimation; arXiv:2005.06897 [cs.LG], 2020, the entire contents of which is incorporated herein by reference. Additional neural network configurations such as deep neural networks (DNN) and support vector machines (SVM) have been implemented in connection with autonomous vehicle operation such as described in U.S. Pat. Nos. 10,054,445, 11,562,231 and 11,508,049, the entire contents of these patents being incorporated herein by reference, and also in US application 2022/0332335, or a convolution neural network (CNN) as described in US application 2021/0191424, the entire contents of these applications being incorporated herein by reference. The aforementioned computational methods generally comprise iterative sequence of steps whereby an error metric is defined for the specific application and the iterative sequence minimizes the error metric to generate an output value that is utilized by the system to record or communicate corrected position and heading information of to adjust an operating parameter for the inertial sensor, such as a drive frequency or sampling rate, of to adjust an operation of a moving object being sensed such as an autonomous vehicle. Such feedback control or closed loop control can improve the measurement accuracy of the inertial sensor or other sensors being used to monitor conditions as described herein.

The present invention is especially adapted for use in object-detecting systems, which are used to determine at least one of the range, angle and velocity of a target. Broadly described, the present invention is concerned with the mounting of MEMS IMUs, and particularly 3DS MEMS IMUs, onto individual sensor elements or subarrays of such sensor elements of position-detecting system. Given their small size, weight and reduced power consumption, and provided they allow for a minimal bias instability, such as below 1 deg/hr, MEMS-based IMUs including accelerometer and angular rate sensors (6 DOF MEMS IMUs) can be mounted directly on some, and preferably on each, sensor element. The measurement signals of the MEMS IMUs can be processed directly at the sensor element, by the MEMS processing circuitry or by the sensor element processing unit, or they can be sent to a central processing unit allocated for a sub-set of the sensor elements.

LiDAR (Light Detection and Ranging) is rapidly becoming a key element in ADAS (Advanced Driver Assistance Systems) and autonomous vehicle navigation. LiDAR was developed for survey and mapping. It can produce very accurate 3D measurements of the local environment relative to the sensor. This accuracy is achieved by the emission of thousands of pulses of laser light per second and the measurement of the time of flight (TOF) between emission and the collection by a sensor of the reflected light from the environment.

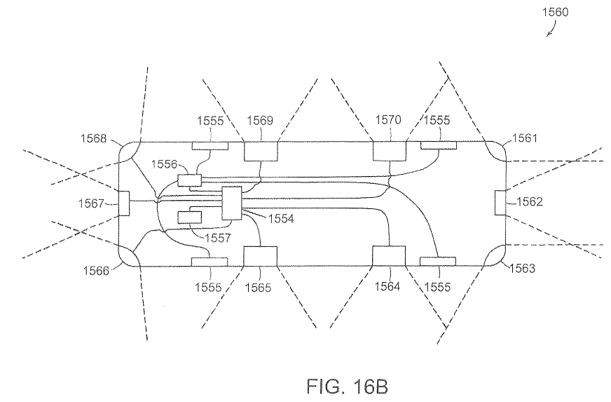

Shown in FIG. 16A is a multimodal sensor system for an autonomous vehicle 1540 wherein forwarding looking sensors include a camera field of view 1545 for traffic sign recognition, LiDAR field of view 1544, longer range radar FOV 1542, and optional shorter range radar FOV 1546 and ultrasound 1549 that looks in both forward and rear directions for close proximity warning. Side camera 1547 and rear side looking radars 1548 and camera 1551 can also be used.

Thus, the array of modules on different sections of a wheeled ground vehicle or automobile can have selected combinations of sensors. A forward looking module is preferably configured with a plurality of sensors operating in different modes such as a radar emitter and detector, one or more cameras, a LiDAR sensor, and an ultrasound sensor which can operate to sense obstacles at different ranges. Sensor fusion programs can be used by the processor 1554 to simultaneously process data from each of the plurality of sensors and automatically send navigation and control commands to the braking and steering control systems (described below) of the vehicle 1540. Simultaneous location and mapping (SLAM) programs have been extensively described in the art such as, for example, in U.S. Pat. Nos. 7,689,321 and 9,945,950, the entire contents of these patents being incorporated herein by reference.

The sensor array distribution is seen in FIG. 16B for autonomous vehicle 1560 operated on wheels 1555 with the array of sensor modules 1561-1570 distributed around the vehicle and connected to processor 1554. Each of the sensor modules 1561-1570 can perform one or more sensing functions as described above including acquiring a camera FOV 1545, 1547, 1551, LIDAR FOV 1544, long range radar FOV 1542, 1548 short/medium range radar FOV 1546, or ultrasound 1549. Each sensor module 1561-1570 can send ranging data to or receive instructions from the processor 1554 in various embodiments. The wheels 1555 include brakes. The brakes can include sensors that detect data related to the wheel 1555 or brake status (e.g., wheel revolutions per minute, brake actuation status, percentage of braking applied). The brake sensors are operatively coupled to a braking module 1556 that is in communication with the processor 1554. The braking module 1556 can receive data related to the wheel 1555 or brake status and can selectively control the brakes stop the autonomous vehicle 1560. The processor 1554 can control the braking module 1556 to apply the brakes based upon an analysis of ranging data received from the array of sensor modules 1561-1570 to enable the autonomous vehicle 1560 to avoid collisions with objects.

The autonomous vehicle 1560 can also include a steering module 1557 that is in communication with the processor 1554. The steering module 1557 can control a steering mechanism in the vehicle to change the direction or heading of the vehicle. The processor 1554 can control the steering module 1557 to steer the car based upon an analysis of ranging data received from the array of sensor modules 1561-1570 to enable the autonomous vehicle 1560 to avoid collisions with objects.

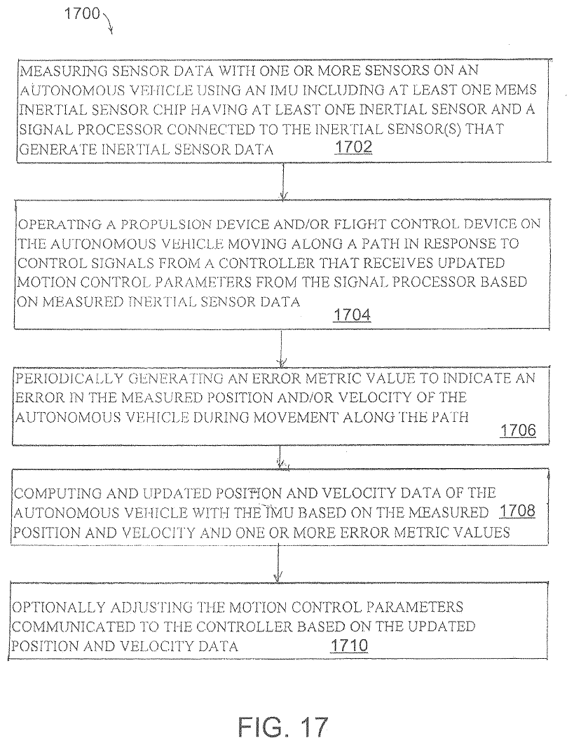

FIG. 17 is a process flow diagram illustrating a method of measuring sensor data for an autonomous vehicle. Sensor data is measured from one or more sensors on an autonomous vehicle using an IMU (step 1702) including at least one MEMS inertial sensor chip, at least one inertial sensor, and a signal processor connected to the inertial sensor(s) that generate inertial sensor data. A propulsion device and or flight control device is operated (step 1704) on an autonomous vehicle moving along a path in response in response to control signals from a controller that receives updated motion control parameters from the signal processor based on measured inertial sensor data. Error metric values are periodically generated (step 1706) to indicate an error in the measured position and/or velocity of the autonomous vehicle during movement along the path. Position and velocity data are computed and updated for the autonomous vehicle with the IMU based on the measured position and velocity and one or more error metric values. The motion control parameters are optionally adjusted (step 1710) that are communicated to the controller based on the updated position and velocity data.

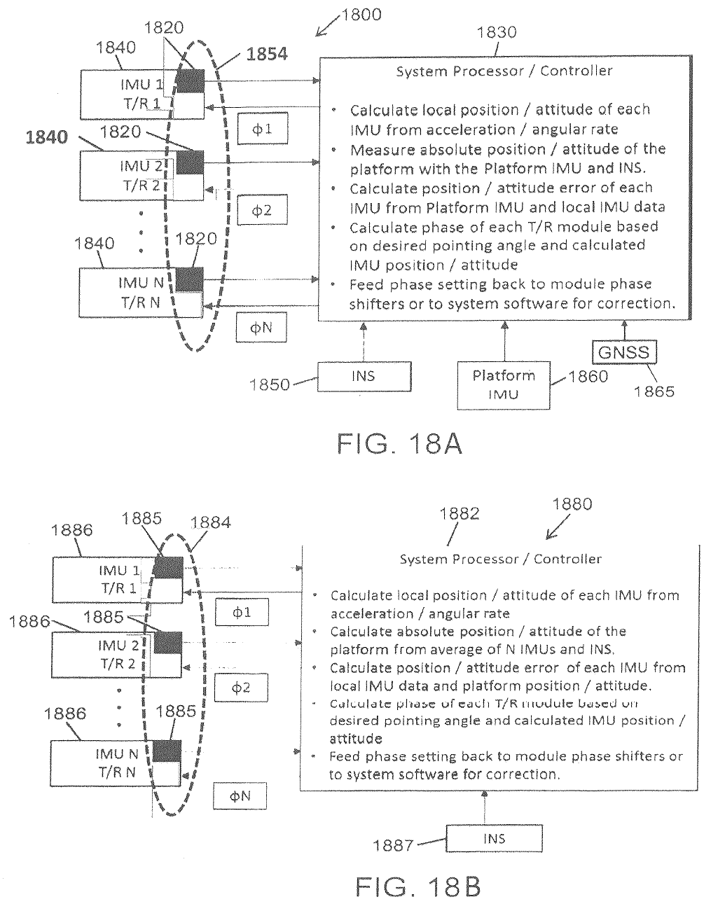

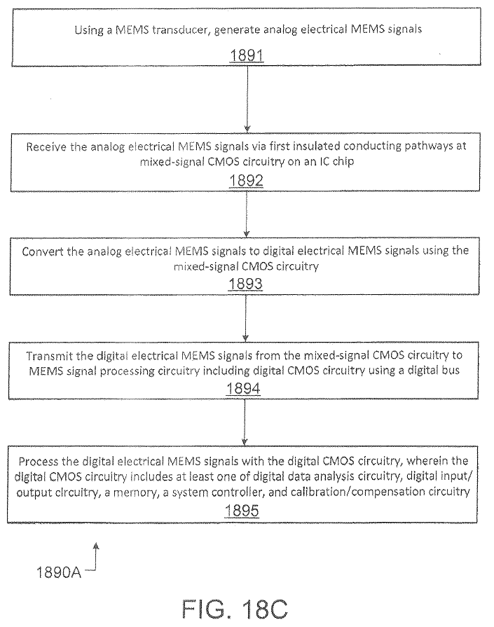

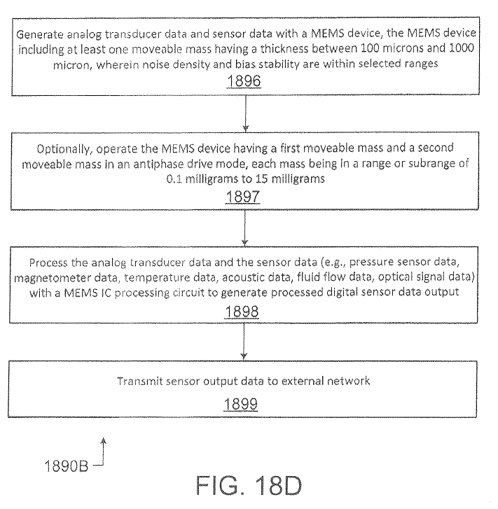

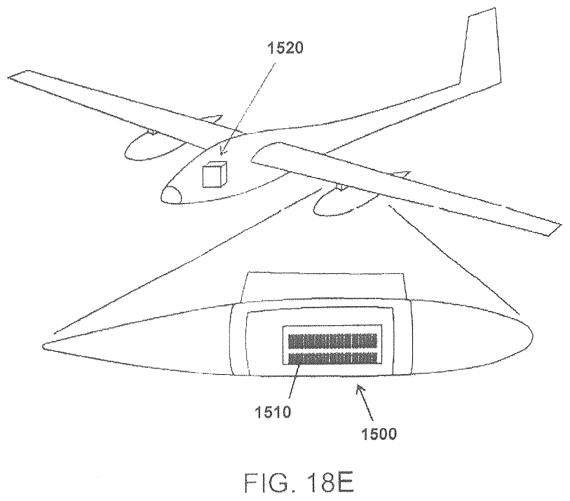

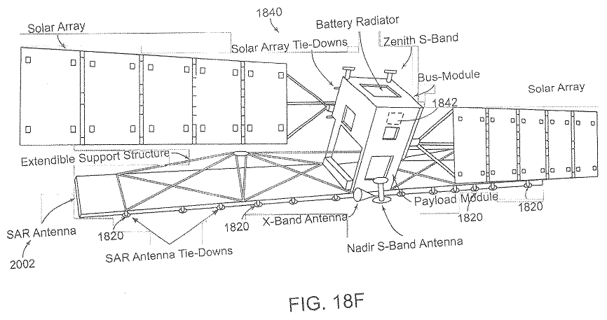

Referring to FIG. 18A, one embodiment of a system process is outlined for a sensor array system 1800 with a platform IMU 1860 and an Inertial Navigation System (INS) 1850. Acceleration and angular rate data from each element's IMU 1820 is fed to a central system processor 1830 which calculates the position, velocity, and attitude of each IMU 1820. The position, velocity, and attitude of the platform are also measured by the platform IMU and inertial navigation system INS. The processor then calculates the absolute position and attitude of each sensor element based on the IMU data and individual MEMS IMU 1840 data. This positional and attitudinal data is then used to calculate the exact phase shift for each sensor element 1840 in order to transmit or receive a signal at a particular pointing angle. The N IMUs 1840 form a “virtual system IMU” (VSIMU) 1854. The central system processor also interfaces a global navigation satellite system (GNSS) 1865.

FIG. 18B illustrates another embodiment of the system 1880 in which there is no platform IMU. Again, acceleration and angular rate data from each element's IMU 1820 is fed to a central processor 1882. Preferably, the higher frequency vibrational data is filtered either electrically or mathematically, through a digital or analog filter from the lower frequency data which includes the translational, rotational, and drift information. The position, velocity, and attitude of the platform can be calculated from the ensemble average of the low frequency IMU data and data from the inertial navigation system 1887. In this way the N IMUs 1886 form a “virtual system IMU” (VSIMU) 1884. As described earlier and illustrated in FIG. 10 the positional and attitudinal data for each MEMS IMU 1885 is then used to calculate the corrected phase shift for each element in order to transmit or receive a signal at a particular pointing angle.

Referring to FIG. 18C, a process flow diagram is illustrated that describes a method 1890A of operating a MEMS transducer device. Analog electrical MEMS signals are generated using a MEMS transducer (step 1891). The analog electrical MEMS signals are received via first insulating conducting pathways at mixed-signal CMOS circuitry on an IC chip (step 1892). The mixed-signal CMOS circuitry converts the analog electrical MEMS signals to digital electrical MEMS signals (step 1893). The digital electrical MEMS signals are transmitted from the mixed-signal CMOS circuitry to MEMS signal processing circuitry including digital CMOS circuitry using a digital bus (step 1894). The digital CMOS circuitry processes the digital electrical MEMS signals (step 1895). The digital CMOS circuitry includes at least one of digital data analysis circuitry, digital input/output circuitry, a memory, a system controller, and calibration/compensation circuitry.

Referring to FIG. 18D, a process flow diagram illustrated that describes a method 1890B of operating a proof mass MEMS device in accordance with preferred embodiments of the invention. Transducer data and sensor data are generated with a MEMS device (step 1896). The MEMS device includes at least one moveable mass having a thickness between 100 microns and 1000 microns. The mass area and thickness are chosen to provide noise density and bias stability values within selected ranges. Optionally, the MEMS device having a first moveable mass and a second moveable mass is operated in an antiphase drive mode (step 1897). Each mass being in a range or subrange of 0.1 milligrams to 15 milligrams. A plurality of masses are selected to reduce noise. The transducer data and the sensor data (e.g. pressure sensor data, magnetometer data, temperature data, acoustic data, fluid flow data, optical signal data) are processed with a MEMS IC processing circuit to generate digital sensor data output (step 1898) as described herein. The device can then transmit to sensor output data by wired or wireless transmission to an external application by a communication network.

Another example for an autonomous vehicle having a central IMU 1520, an exemplary sensor array is a synthetic aperture radar (SAR) 1500 as shown in FIG. 18E. The SAR unit can have one or more sensor elements 1510. This can be based on a phased array radar. What differentiates the SAR is that its position changes over time. By processing the returns from the target for the entire time, it is illuminated by the beam, a short antenna can operate as if it was much longer than its actual length, providing improved spatial resolution.

While this example provided above are based on radar technology, the principle of the present invention can also be used in sonar systems, or any detecting and/or positioning systems comprising a plurality of sensing and/or emitting elements, such as T/R modules. For example, multi-beam sonars are used to plot sea bottom topology by using a transmitted acoustic beam that is narrow along the ship track and wide across track. There are many received beams, but each is long along the track and narrow across track. The intersection of the transmit beam and individual receive beams provides the depth information at that point. It is necessary to know the position and attitude of the acoustic transmit and receive modules in time to accurately map the sea floor. A towed sonar array can have a towed transmitter and a separate array of towed receivers that are mounted on flexible cables that can move relative to each other. Again it is necessary to know the positions and attitudes of the transmitters and receivers relative to each other and to their position in the ocean.

As a further example, one of the more complex and largest deployable antenna types is shown in the satellite 1842 of FIG. 18F having a central IMU 1844 and additional IMUs 1820 as described herein for sensors distributed across the satellite array. The deployable antenna described therein is an example of using a complex mechanism to achieve several objectives including fitting a large area structure in a small volume, reliable and precise deployment, achieving a high degree of precision in ‘flatness’ (usually measured in roughness), high stiffness with light weight, and very light non-payload deployment mechanism elements (i.e., the non-operational aspects of the antenna once deployed). In some embodiments of the mesh style antenna described therein the elements can be built of materials that are highly thermally stable. The inertial sensor chip package described herein enables more precise operation of satellite attitude orbit control systems (AOCS) for space vehicles and satellites as well as for re-entry vehicles.

The use of precise, small, low power 6 DOF (or higher DOF) MEMS IMUs 1820 on these antennas is important because of their ability to measure precisely angular and linear acceleration. Such measurements are important in characterizing the performance of the antenna in research, development, manufacturing, deployment, operation, stability, movement, and deterioration.

Motion detection methods described herein are pertinent to fixed, mobile and deployable antennas, solid or mesh reflectors, active or passive arrays, active, passive, acoustic, electromagnetic, and other phenomenon-sensing systems, terrestrial, underwater, and spaceborne apertures, monostatic radars, bistatic radars, multistatic radars, MIMO radar, and SIMO radar.

One very important area for the application of 3DS MEMS to antenna surfaces arises when the aperture, i.e., the antenna area, goes from a rigid unibody reflective surface to a collection of reflective elements of a single antenna aperture integrated over time, often with techniques termed Synthetic Aperture, yet still a monostatic system, or a pseudo-monostatic system (i.e., one in which the actual transmit and receive apertures are separate but at a trivial distance such that they are close enough to be considered a single system for signal processing purposes).

The next embodiment relates to bistatic radars, in which the transmit and receive apertures are separated by a non-trivial distance. Again, the motion detection of the gross and finite elements of the receive aperture approximate a single system.

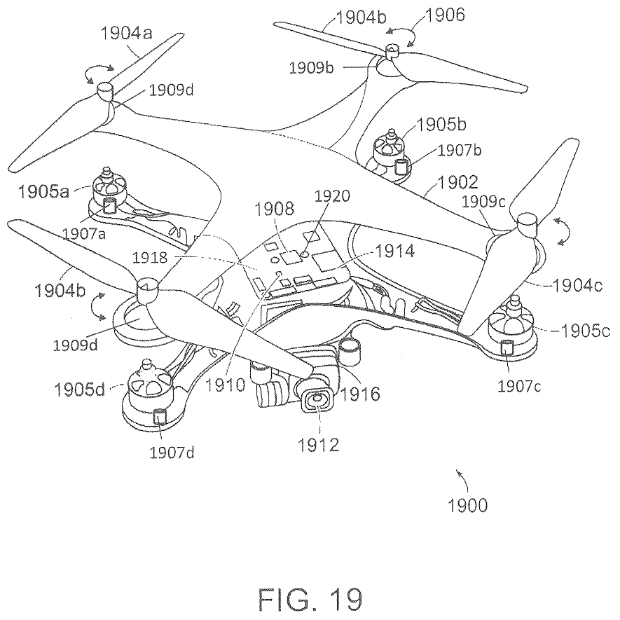

Time Difference of Arrival (TDOA) is a method of determining the Angle of Approach (AOA) of an incoming wave, which can be acoustic, radio frequency, or light. As shown in FIGS. 18 and 19, the wider the separation distance 1802 the larger the effective baseline 1804 with fixed, surveyed, unmoving receive apertures. The known distance X 1806 is the additional distance the wave 1800 must travel to reach the left hand aperture 1803 after the wave 1800 has reached the right hand aperture 1805. The speed can be a constant such as the speed of light or a medium-dependent speed such as the speed of acoustic waves through the atmosphere or water.

The MEMS die is inherently highly radiation proof and thus is well suited for spacecraft applications such as satellites. The ASIC can be replicated in radiation-hard material with radiation-hard design practices to make a space-qualified 3DS MEMS. Motion data from the 3DS MEMS can be processed at full data rate or at a sampling rate, allowing edge processing and reporting at low data rates. Both approaches will provide useful data.

Transmit and receive modules are critical to many types of advanced Synthetic Aperture Radar (SAR) and Inverse (ISAR) systems. SAR and ISAR systems are highly dependent on absolute movement, i.e., motion of the entire system, and relative motion (motion of the elements of the antenna in relation to each other), which can be measured by sensing rotational acceleration (measured by gyroscopes) and linear acceleration (measured by accelerometers) as described herein. A single 6 Degree of Freedom (6 DOF) MEMS IMU can include 3 gyroscopes and 3 accelerometers, for example.

An important aspect for large sensor arrays relates to “lever arm”—the distance between any element in motion and the center of the IMU. Placing the MEMS at the T/R module, for example, makes the moment arm negligible.

The 3DS MEMS is inherently resistant to high power radiation and temperature, which can be the environment of a T/R module. This design provides a high degree of accuracy in the small space dictated by the design of high power, high frequency T/R modules.

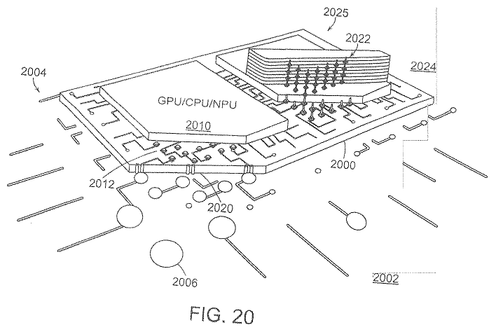

Placing 3DS MEMS IMUs in each T/R module provides gross and fine position and movement data. For example, the satellite of FIG. 20 has very long deployable radar panels that have embedded T/R modules. The multi-section, deployable SAR Antenna is subject to multiple sources of positional error, including but not limited to 1) transit, launch by an autonomous or manned rocket launch vehicle or deployment to include bending, warping, and 2) movement in operation because of thermal loading and distortion, spacecraft acceleration or repositioning, solar winds, or even impact with space debris. The outermost portion of such a long rectangular antenna, or even a round antenna, is most vulnerable to motion because of the lever-arm, the distance from the center, most solidly mounted and closest to the spacecraft body.

The impact of the distances between elements of the motion detection elements (e.g., GPS, IMU) and the theoretical center of the antenna and the actual discrete areas of the antenna is important. In this invention the lever-arm is such that any precise calculation of positioning and navigation data using exterior input such as satellite data from a Global Navigation Satellite System (GNSS) such as GPS along with IMUs, require that the lever-arm must be precisely measured.

Current practice is to use a single solution wherein a typical satellite, aircraft or ship uses both GPS and IMU information. The lever-arm between those units, and between them and the antenna aperture must be carefully calculated. In state of the art practice today, the center of the antenna aperture is used to approximate the motion for the entire aperture. The lever-arm is defined as the perpendicular distance from the fulcrum of a lever to the line of action of the effort or to the line of action of the weight.

All radar techniques require detailed knowledge of motion and compensation. Additional techniques beyond SAR and ISAR include Interferometric SAR (InSAR) in which two separate SAR images are taken from two different tracks. This and other types of advanced processing place a premium on precise motion data for compensation.

Another type of imaging radar for spacecraft or aircraft is bistatic (e.g., using one platform to transmit, or “forescatter” RF energy, and a second one to receive the backscattered, or reflected energy.) In the example of the satellite in FIG. 20, the SAR antennas are 15 m long and 1.5 m wide and weigh 700 kg. As the satellite body is about 1.5-2.4 m wide, the center of the antenna is up to 16 m from the farthest T/R elements. Such a lever-arm means that positional errors are greatly compounded. The MEMS array of sensors is distributed along the antenna at different distances from the center to address this problem. The plurality of IMUs generate data from different positions along the antenna that can be used to time the transmitted and received signals.

FIG. 19 is an illustration of a drone (or vehicle) that can fly autonomously. The drone includes a body 1902 and four rotors 1904a, 1904b, 1904c and 1904d. The rotors are driven by drives (or motors) 1905a, 1905b, 1905c and 1905d. The drives and rotors can tilt 1906 to actuate a motion. In this way the drone can move translationally through the air as well as maintain drone or vehicle attitude. Each drive has an IMU located next to the drive. IMU 1907a is situated next to drive 1905a. IMU 1907b is situated next to drive 1905b. IMU 1907c is situated next to drive 1905c. IMU 1907d is situated next to drive 1905d. Each drive tilts while driving a rotor and can move through a tilting clearance space. Drive 1905a tilts through tilting clearance space 1909a. Drive 1905b tilts through tilting clearance space 1909b. Drive 1905c tilts through tilting clearance space 1909c. Drive 1905d tilts through tilting clearance space 1909d. The drone has a camera 1912 and an additional IMU 1916 mounted to the camera assembly to determine the attitude and positon of the camera. The drone has a circuit board 1918 that carries control electronics 1908 an IMU 1914 and a battery 1920. The drives tilt in order to actuate motion in alternate embodiments the drive and rotor combination are on arms that can tilt or swivel so that the thrust from each rotor may be vectored.

Shown in FIG. 20 is a stacked integrated circuit 2000 having one or more MEMs inertial sensors and/or other MEMs transducers such as that shown generally in FIGS. 3A and 3B, for example, that are further incorporated into a 3D circuit having an integrated circuit 2004 mounted on a circuit board 2002 in which solder balls 2006 provide pathways for electrical signals are routed between layers in the circuit 2000. Through silicon vias 2020 as described herein can electrically connect a first side of the IC 2004 to a second sideA signal processing circuit 2010 can be mounted on the IC 2004 with microbumps 2012 routing electrical signals between the IC 2004 and the processing circuit 2010. The processing circuit can comprise an FPGA, a CPU, a GPU or a neural processing unit (NPU) as described herein, or a combination of such processing chips mounted in a single layer or multiple layers of the IC stack 2000. The central processing unit (CPU) can control operational parameters of the inertial sensor system and/or control an operation of an autonomous vehicle in which it is mounted, for example. The graphics processing unit (GPU) can perform sensor fusion operations, or iterative computational operations for a machine learning process by which inertial sensor data and other onboard sensors can be used to compute adjusted position, velocity and acceleration data for an autonomous vehicle, for example, and consequently operate to control the position and heading of an autonomous vehicle. The 3D circuit 2000 can be mounted on MEMs chip as described herein, or one or more MEMs chips can be mounted on the circuit board 2002 wherein MEMs sensor signals are routed for further processing and/or digitized for storage and/or further processing.

Also mounted on the IC 2004 is a stack of memory circuits 2024 such as DRAM chips connected by vias 2022 that can be configured as a high bandwidth memory 2025. This memory can provide an on-package cache to support operations of the processing circuitry 2010 as described herein wherein inertial sensor data generated by the MEMs inertial sensor(s) can digitized and processed as described herein. The IC 2004 can perform computational processing of real time sensor data, fuse the sensor data, and generate further feedback control functions, such as compensation of sensor data, monitor the state(s) for operation of a system connected to IC circuit 2000. The memory 2025 is connected to the memory controller of a CPU or GPU for example. The memory can also provide storage for one or more image sensors connected to the IC circuit 2000.

NVIDIA, a manufacturer of processing platforms and processing devices has released the NVIDIA GH200 Grace Hopper Superchip. The device is a system on a chip (SOC) design that enables processing of sensor data fusion for navigation and control system for an automotive autonomous vehicle with input from an external commercial grade IMU. The device contains a 72core NVIDIA Grace CPU, a NVIDIA H100 Tensor Core GPU, up to 480 GB of LPDDRSX memory with error correction (ECC). The device supports 96 GB of HBM3 or 144 GB of HBM3e and up to 624 GB of fast access memory. It also supports NVLink C2C of coherent memory. The use of this type of device and its use for an autonomous vehicle navigation and control system is described in detail in U.S. Pat. No. 11,688,181 B2 issued on Jun. 27, 2023 the entire contents of which is incorporated herein by reference.

Unmanned Vehicles (UVs), particularly Unmanned Air Vehicles (UAVs), have become pervasive in defense and commercial applications. Inertial Measurement Units (IMUs) are essential in determining the position and attitude of the UAV. Kalman filtering and machine learning (ML) as described above are used in numerous ways to plan, monitor, and predict the flight path and attitude of the UAV. IMUs are also important for improving the performance of optical sensors, particularly imaging devices such as CMOS imagers enable use of situational awareness and mapping, which can also be used for navigation. Although too numerous to list in detail these algorithms include Kalman filters to iteratively predict the state of an IMU at a future time and then update those predictions with new measurements, and machine learning for attitude control, parameter tuning, adaptive control, and collision avoidance. UAV attitude is important not only for state description, but also for positioning for image stabilization and thrust management in the case of fixed rotor UAVs. Additionally, ML is used to identify deviations from the set flight path due to various disturbance factors, by finding the abnormal situation in time and take corresponding measures. These methods can identify anomalies in real time and can adjust the state or operative condition of a system in response.

In all these applications the accuracy of the algorithm or machine learning model is invariably determined by comparing the predicted flight path to the “actual” or “measured one” based upon readings from the IMU, sometimes coupled with GPS or GNSS system or other navigational systems such as LEO (low earth orbit) based systems of M-coded systems. This is typically accomplished using a Root Mean Square Error (RMSE) approach where

$$RSME = \sqrt{\frac{1}{N} {\sum }_{1}^{N} {( {y}_{p} - {y}_{m} )}^{2}} \qquad ( 7 )$$

where N is the number of data points, yp is the predicted value and ym is the measured value. Thus, the accuracy of the IMU (ym) is critical in determining both the accuracy of the learning algorithms and the quality of the flight prediction algorithms. Some of the key parameters for determining the accuracy of the IMU are the bias or bias offset (the output of each of the accelerometers and gyroscopes with zero acceleration or angular rate input), scale factor non-linearities, Angular and Velocity Random Walk (ARW and VRW), and Bias Instability (BI). The bias offset, which can vary from turn-on to turn-on) and scale factors can be compensated for, but the ARW, VRW, and BI set fundamental limitations on the accuracy of the IMU. The ARW (in deg/√sec) and VRW (in m/sec2/√Hz) are measures of the errors introduced by thermal (random) noise to the gyroscopes and accelerometers respectively. The thermal noise error can be reduced by averaging and decreases with the square root of the measurement or averaging time:

$$\partial ω = ARW * τ \hat{} ( - 1 / 2 ) \qquad ( 8 )$$

where ∂ω is the error in angular rate and τ is the averaging time, and similarly,

$$\partial a = VRW * τ \hat{} ( - 1 / 2 ) \qquad ( 9 )$$

where ∂a is the error in the acceleration measurement.

Higher measurement accuracy can be achieved with longer averaging times. However, the longer period between measurements can miss or average out small changes in angle or position. Thus lower ARW and VRW enable measurement of smaller, quicker changes in motion. Additionally, regardless of the averaging time the angular and position error grow over time:

$$\partial θ = ARW * τ \hat{} ( - 1 / 2 ) \qquad ( 10 )$$

$$and$$

$$\partial p = ( 1 / 2 ) VRW * τ \hat{} ( 3 / 2 ) \qquad ( 11 )$$

where ∂θ and ∂p are the errors in angle (attitude) and position respectively. In fact, a more detailed analysis of position error due to uncertainty in the positions of the x, y, and z axes due to uncertainty in the attitude of the system yields an even stronger dependence of position upon the angular rate error:

$$\partial p = ( 1 / 6 ) ARW * 〚 g * τ 〛 \hat{} ( 5 / 2 ) \qquad ( 12 )$$

The advantage of the 3DS MEMS IMU for navigation in a UAV is the increased accuracy due to the reduced ARW and VRW due to the large proof mass coupled with its small size.

In an article titled “Adaptive support vector regression for UAV flight control” by Jongho Shin, H. Jin Kim and Youdan Kim published in Elsevevier (Neural Networks 24(2011) 109-120) which is incorporated herein by reference in its entirety. The article describes kernel based learning methods such as Support Method Machine (SVM) and Support Vector Regression (SVR) which transform the control of autonomous vehicle navigation and control into quadratic programming problems (QP) whose global solution can be obtained by QP solvers. As stated in the article the output of an offline trained 1 SVR can be represented by equation 13 and is given;

$${\hat{u}}_{i , ( . )} ( {X}_{( . )} ) = {\sum }_{j = 1}^{{L}_{i , ( . )}} {ζ}_{i , j , ( . )} κ ( {X}_{( . )} , {X}_{i , j , ( . )} ) + {c}_{i , ( . )} , i = 1 , 2 \qquad ( 13 )$$

### Where:

L_{i,(.)} is the number of support vectors of the iₜₕ 1 SVR in each model,
X_{(.)} is an input vector, X_{i,j,(.)} is a support vector
u_{(.)} is an approximated output value based on the nominal model.

An associated error dynamic can be expressed in equation 14 and is given:

$${\dot{e}}_{ι} = {A}_{i} {e}_{i} + b {\tilde{ω}}_{i}^{τ} {κ}_{i} ( x ( τ ) , \dot{x} ( τ ) , {u}^{\dot{\hat{}}} ( τ ) ) \qquad ( 14 )$$

Where position x(t) and velocity \dot{x}(t) and control command u(t). Thus, this error metric can be employed for control of a UAV, for example, in which the position, velocity and acceleration data at each measurement interval generates an error value. Values above a threshold can be used to modify the inertial sensor data being processed and thereby generate more accurate control parameters for real time precise and continuous vehicle control including updated position and heading.

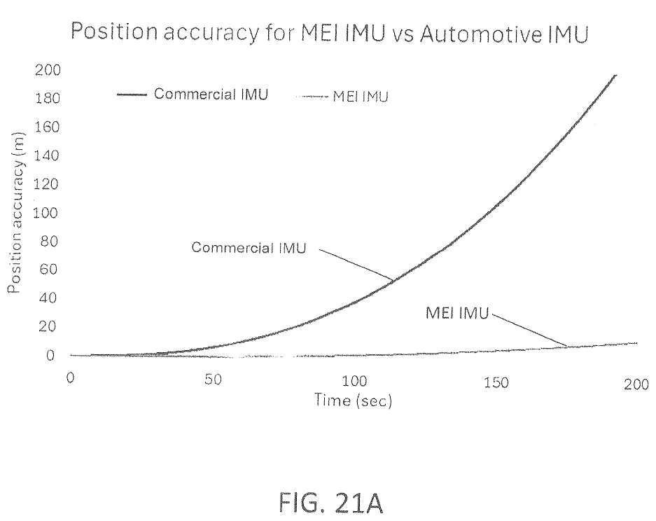

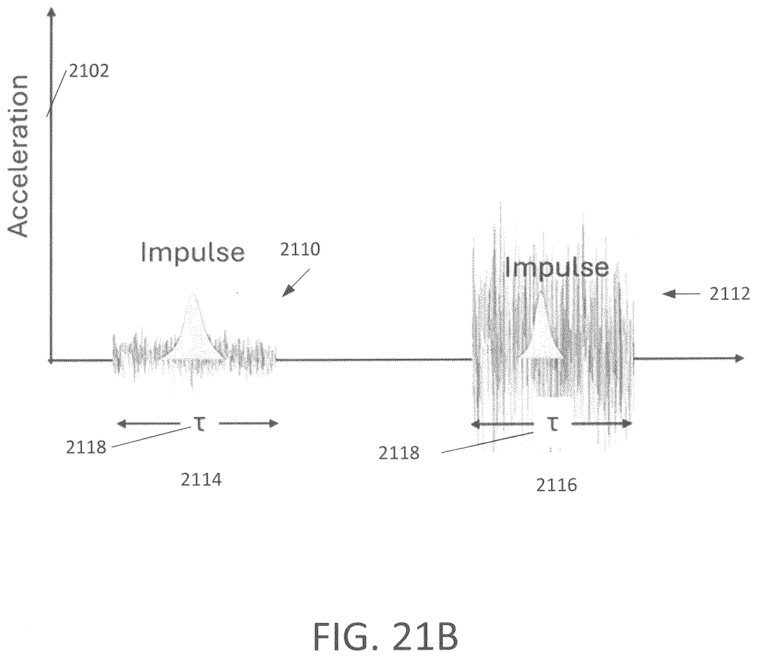

FIG. 21A is a plot of the total positional error due to a 6 axis IMU as a function of time comparing the 3DS IMU to another small commercial IMU. The inaccuracy of the consumer device diverges from the 3DS IMU over time, limiting the amount of time that the IMU can be used for dead reckoning. A typical figure of merit for an IMU is how long it can maintain accuracy better than GPS (about 10 m). The 3DS IMU can “dead reckon” better than 10 m for about 3 minutes, whereas the consumer device can only go for about 60 seconds. In many applications such as for defense and first responders, the extra time can be critical. Furthermore, increased accuracy leads to more accurate algorithms because of equation (7) and quicker convergence of the ML learning process.

Accuracy similar to the 3DS IMU can be achieved with fiber optics gyroscopes and quartz vibrating beam accelerometers, but these devices are much more expensive, larger, and heavier. Besides increasing the payload of the UAV, the number of devices must be limited. The size of the 3DS IMU enables multiple IMUs to be located on the system where required: center of mass, imager gimbal, thrusters, etc. The placement of multiple IMUs enables additional positional input data for the system parameters providing more data for machine learning for system control.

Finally, the increased accuracy of the IMU enables deviations from the desired path or external disturbances such as wind or shocks to be identified more quickly and more sensitively. FIG. 21B shows the acceleration 2102 measurement of an impulse or shock 2110 and 2112 during a measurement period t 2118 with the 3DS accelerometer 2114 and the commercial accelerometer 2116. The white noise figures for each are roughly proportional to the VRWs of each (˜5 ug/rt-Hz for the 3DS IMU and 175 ug/rt-Hz for the automotive). An impulse disturbance that can be measured by the 3DS IMU 2114 is completely obscured by the noise of the automotive IMU. For example, if the measurement period is 0.01 sec, then the average acceleration noise (accuracy) for the 3DS and automotive accelerometers are 50 ug and 1.75 mg respectively. Thus the 3DS can measure a much lower acceleration disturbance than a less accurate automotive sensor.

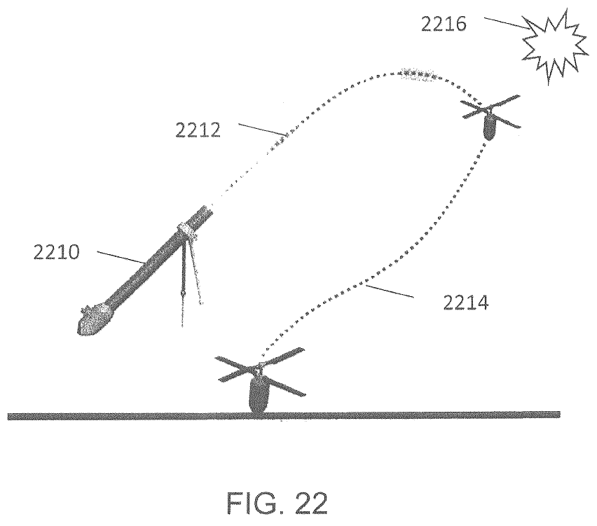

The multiple-range accelerometer design illustrated in FIGS. 1-7 also aids AI-based navigation in dealing with strong external factors that could alter the planned flight path. These can include wind gusts, shocks, or even unexpected obstacles. For moderate flight speeds and perturbations, e.g. light wind, a single accurate IMU can measure the moderate impulses or changes in acceleration due to the perturbation and provide steady data to the processing engine. However, if the perturbations are strong, e.g. high wind gusts or shock waves, it is possible for the resulting acceleration to exceed the accelerometer range being used for accurate navigation (typically ˜10 g). These “high-g” situations can often occur in launched UA Vs and Precision Guided devices (PGMs) during launch using rockets or re-entry vehicles entering the earth's atmosphere at hyperonic velocities. The multi-range accelerometer can include at least a low-range navigation accelerometer (˜+/−10 g) and a high-range accelerometer (e.g., +/−100 g). The navigation system can monitor both accelerometers, using the more precise low-range one for navigation. When the system detects an over-range event for the low-range sensor, the navigator can switch to the high-g accelerometer, smoothly compensating for the disturbance, then switch back to the low range when the disturbance is over. This capability is particularly helpful in measuring the motion during launch, which is typically hard to do. If launch accelerations exceed the high-g values that might be expected during flight, an additional “very-high-g” accelerometer with range over 100 g can also be included. The 3DS architecture provides built-in mechanical over-range protection which has been shown to exceed 14,000 g. Thus the multiple range accelerometer can survive these high-g events, and the high or very high g accelerometers can measure through them. Such a flight is illustrated in FIG. 22.

FIG. 22 is a diagram showing a high g impulse during a navigation scenario. FIG. 22 shows the launch of vehicle navigating in a low g navigation environment 2114. The launch of countermeasures 2210 at a very high g is one example. The countermeasures navigate a ballistic flight at a relatively low g. The countermeasure introduces a high g impulse at 2216 to the navigation scenario so that the neural processor generates dynamically varying control signals to navigate through the high g impulse.

From this the conclusion is drawn that using one or more 3DS IMUs to provide more accurate training data for the computaional learning algorithm. Using one or more 3DS IMUs to provide more accurate and faster data to the navigation/orientation/path-planning algorithm for quicker convergence on a solution. Using the 3DS IMU to provide more sensitive feedback on external disturbances affecting the navigation path. Using multiple 3DS IMUs on various system parts that may be moving relative to the UAV center of mass: COM, movable or fixed thrusters, movable imaging systems. and finally using a multiple range accelerometer to detect and measure through high-g events in a planned flight including launch, high winds, shock waves, and quick motions to avoid obstacles, for example.

The scope of the claims should not be limited by the preferred embodiments set forth in the examples, but should be given the broadest interpretation consistent with the description as a whole including any equivalents.

1. An inertial sensor chip package for an autonomous vehicle comprising:
an inertial sensor having a proof mass formed in a device layer of a silicon-on-insulator (SOI) MEMS wafer, the proof mass being supported by springs formed with the device layer over an insulating layer and a handle layer, the inertial sensor positioned within a chip package mounted on an autonomous vehicle and including a clock that controls signal processing operations of a chip controller, wherein the proof mass is within the range of 0.1 to 15 milligrams; and
a processing circuit connected to the inertial sensor within the chip package that receives inertial signals from the inertial sensor and computes a change of position of the inertial sensor wherein the processing circuit outputs a signal corresponding to the change of position to control a motion of the autonomous vehicle.

2. The chip package of claim 1 wherein the inertial sensor comprises a first accelerometer aligned with a second accelerometer, the first accelerometer configured to generate first accelerometer signals over a first acceleration range and the second accelerometer configured to generate accelerometer signals over a second acceleration range different from the first acceleration range.

3. The chip package of claim 2 wherein the first accelerometer and the second accelerometer are coplanar.

4. The chip package of claim 1 further comprising a gyroscope formed in the device layer and having a noise density in a range of 0.005 deg/hr to 0.1 deg/hr, and having a bias stability in a range of 0.05 deg/hr to 1 deg/hr.

5. The chip package of claim 2 wherein the first accelerometer proof mass comprises a device layer, an insulating layer and a handle layer, the proof mass being movably mounted in a cavity with the springs, the accelerometer having a bias stability in a range of 0.5 micro-g to 10 micro-g and a noise density in a range of 3 micro-g/Hz to 30 micro-g/Hz.

6. The chip package of claim 2 wherein the processing circuit comprises a low pass filter and a high pass filter and further comprises a lock-in amplifier to detect a frequency of motion above a resonant frequency of at least one proof mass.

7. (canceled)

8. The chip package of claim 1 further comprising a data processor connected to receive digitized sensor signals for processing of inertial data.

9. The chip package of claim 1 wherein the device further comprises an inertial measurement unit (IMU).

10. The chip package of claim 1 further comprising a top cap SOI wafer that is fusion bonded to the SOI MEMS wafer and a conductive single crystal silicon bottom cap wafer.

11. (canceled)

12. The chip package of claim 10 wherein the inertial measurement unit further comprises a gyroscope proof mass coupled to a frame with a plurality of springs.

13. (canceled)

14. The chip package of claim 9 wherein the IMU further comprises a neural processor including at least one CPU that controls an operation of an autonomous vehicle and at least one GPU that performs an iterative computational process with inertial sensor data.

15. (canceled)

16. The chip package of claim 1 wherein the accelerometers comprise an inertial sensor that is stacked vertically with the processing circuit to form a single chip package.

17. The chip package of claim 1 wherein the inertial sensor device comprises a three degree of freedom (DOF) device, a six DOF device or a ten DOF device.

18. The chip package of claim 1 further comprising driving electrodes for actuating a motion of one or more proof masses at a frequency, and optionally wherein the driving electrodes are formed in one or both device layers of the SOI cap wafers, and/or in a frame of the SOI MEMS wafer.

19. The chip package of claim 1 wherein sensing electrodes are formed in one or both device layers of SOI cap wafers, and/or in a frame of the SOI MEMS wafer.

20. The chip package of claim 1 wherein the processing circuit comprises a CPU and a GPU.

21. The chip package of claim 1 wherein the processing circuit comprises a neural processor performing an iterative computational process to generate corrected position data.

22. (canceled)

23. The chip package of claim 21 wherein the device further comprises an inertial measurement unit (IMU).

24. The chip package of claim 21 further comprising a top cap SOI wafer that is fusion bonded to the SOI MEMS wafer to form an hermetically sealed cavity and a conductive single crystal silicon bottom cap wafer.

25. (canceled)

26. The chip package of claim 23 wherein the inertial measurement unit further comprises a gyroscope proof mass coupled to a frame with a plurality of springs and optionally wherein the IMU further comprises a position sensor such as a GPS or GNSS sensor.

27. (canceled)

28. (canceled)

29. (canceled)

30. (canceled)

31. (canceled)

32. The chip package of claim 21 wherein the processing circuit comprises a system controller connected to the neural processor.

33. The chip package of claim 21 further comprising a connection to an autonomous vehicle such as an aerial drone or a ground vehicle.

34. (canceled)

35. (canceled)

36. The chip package of claim 21 wherein at least one proof mass moves in a single plane through the MEMS SOI wafer and/or at least one proof mass moves out of a plane extending through the MEMS SOI wafer.

37. (canceled)

38. A method of inertial sensing comprising:
sensing a motion of a first proof mass formed in a device layer of a silicon-on-insulator (SOI) MEMS wafer having the device layer over an insulating layer and a handle layer, the first proof mass positioned relative to first sensing electrodes to measure first inertial sensor signals;
sensing a motion of a second proof mass formed in the device layer of the SOI MEMS wafer, the second proof mass positioned relative to second sensing electrodes to measure second inertial sensor signals;
processing signals with a processing circuit that receives the first inertial sensor signals and the second inertial sensor signals, the processing circuit including a neural processor performing an iterative computational process to generate corrected attitude data.

39. The method of claim 38 wherein the first proof mass comprises a first accelerometer that is aligned with the second proof mass comprising a second accelerometer and wherein the first accelerometer and the second accelerometer are coplanar.

40. (canceled)

41. (canceled)

42. The method of claim 38 wherein at least one proof mass comprises a gyroscope proof mass formed in the device layer.

43. The method of claim 39 wherein the first accelerometer proof mass comprises a device layer, an insulating layer and a handle layer, the proof mass being movably mounted in a cavity with one or more springs.

44. The method of claim 38 wherein the processing circuit further comprises a low pass filter and a high pass filter and wherein the processing circuit further comprises a lock-in amplifier to detect a frequency of motion above a resonant frequency of at least one proof mass.

45. (canceled)

46. (canceled)

47. The method of claim 38 wherein the device further comprises an inertial measurement unit (IMU) and wherein the IMU further comprises a gyroscope proof mass coupled to a frame with a plurality of springs.

48. The method of claim 38 further comprising a cap SOI wafer that is fusion bonded to the SOI MEMS wafer to form an hermetically sealed cavity and further comprising a conductive single crystal silicon bottom cap wafer.

49. (canceled)

50. (canceled)

51. The method of claim 47 wherein the IMU further comprises a position sensor such as a GPS or GNSS sensor.

52. The method of claim 38 wherein the inertial sensor including the MEMS SOI wafer is stacked vertically with the processing circuit in a single chip package, the processing circuit is connected to a further sensor including a camera, or a pressure sensor, or a temperature sensor, or a magnetometer, or a LiDAR, or a radar, or a sonar, or combinations thereof.

53. The method of claim 38 wherein the processing circuit comprises a system controller connected to the neural processor, an analog to digital converter, a memory and a power management circuit.

54. (canceled)

55. (canceled)

56. (canceled)

57. The method of claim 47 further comprising controlling an operation of an autonomous vehicle such as an aerial drone or a ground vehicle.

58. (canceled)

59. The method of claim 38 wherein sensing electrodes and drive electrodes are formed in an SOI device layer of a cap wafer.

60. (canceled)

61. (canceled)

62. The method of claim 57 further comprising performing closed loop control of an operation of a moving vehicle such as an autonomous vehicle, an aerial drone or a satellite.
